(19) United States
(12) Patent Application Publication
(10) Pub. No.: US 2026/0299407 A1
(43) Pub. Date: Oct. 1, 2026

(54) ADDITIVES FOR ORGANOTIN PHOTORESIST COMPOSITIONS AND PATTERNING OF THE SAME

(71) Applicant: Inpria Corporation, Corvallis, OR (US)

(72) Inventors: Alexander C. Marwitz, Corvallis, OR (US); Brian J. Cardineau, Corvallis, OR (US); Matthew Voss, Corvallis, OR (US); Colin T. Carver, Corvallis, OR (US); Kai Jiang, Corvallis, OR (US)

(21) Appl. No.: 19/632,699

(22) Filed: Mar. 30, 2026

Related U.S. Application Data
(60) Provisional application No. 63/780,919, filed on Mar. 31, 2025.

(51) Int. Cl. G03F 7/004; G03F 7/075

(52) U.S. Cl. CPC G03F 7/0042; G03F 7/0048; G03F 7/0752

(57) ABSTRACT

Additives are described to modify and improve radiation patterning properties of organotin compositions. These additives can be organized into five genera of compositions falling within the general formula X—R^{Q}-Q, where X is a hydrogen or a group with a heteroatom, R^{Q} can be a short chain alkyl group or an aromatic moiety depending on which of the five genera are considered. Q can be designed for specific hydrophobic properties or can have specific structures with heteroatoms that can interact with tin cations within the patterning material. The five genera of additive compositions generally function to slow hydrolysis of hydrolysable ligands bound to the tin atoms in the patterning material. Additives are described in the context of precursor solutions as well as in patternable coatings. To achieve a desirable distribution of additive in the deposited coatings, a plurality of deposition steps can be used.

### CROSS REFERENCE TO RELATED APPLICATIONS

This application claims priority to co-pending provisional U.S. application No. 63/780,919 to Marwitz, et al. entitled “WATER ACTIVITY AND ABSORPTION PROFILE TUNING ADDITIVES FOR ORGANOTIN COMPOSITIONS AND PATTERNING OF THE SAME”, which is hereby incorporated by reference in its entirety.

### BACKGROUND OF THE INVENTION

EUV lithography is a cutting-edge technique used to manufacture complex, high density integrated circuit devices and relies on photoresist materials that can offer low defectivity and high pattern fidelity. Among EUV photoresist compositions, organotin-based compositions have received attention and been investigated as potential candidates. Despite progress achieved with organotin materials, several challenges remain. The tin-based compounds may be prone to forming crystalline domains or clusters within the photoresist film which may negatively affect pattern uniformity or resolution. Lithographic patterns formed from photoresists can also suffer from tapered cross-sectional profiles which may negatively affect pattern integrity and consistency. Thus, there remains a demand for EUV photoresist compositions tailored to address these shortcomings.

### FIELD OF THE INVENTION

The invention relates to organometallic, and more specifically organotin, based radiation sensitive patterning compositions comprising one or more additive compounds. The additive compounds can stabilize an organotin photoresist precursor solution and influence coating formation mechanisms to realize enhanced patterning performance and results. The invention further relates to precursor solutions comprising a solvent, an organotin composition and one or more additives compounds, coatings deposited therefrom and lithographic methods for processing said coatings.

### SUMMARY OF THE INVENTION

In a first aspect, the invention pertains to a solution comprising a blend of:
an organic solvent,
an organotin composition represented by the formula RSnL₃, where R is an organyl group with from 1 to 31 carbon atoms and L is a hydrolysable ligand and
one or more additive compositions represented by the chemical formula: X—R^{Q}-Q, wherein the additive groups can be organized into five genera.
1) Q is a low-polarity hydrocarbyl moiety with optional silicon atom substitution and with optional sulfur atom substitution having from 9 to 31 total carbon, silicon and sulfur atoms, R^{Q} is an alkyl group with 1 to 8 carbon atoms or a silyl group, and X is H or a polar functional group comprising a heteroatom.
2) Q is represented by the chemical formula —NR²R³, R² and R³ are independently hydrogen or an alkyl group, X is H and R^{Q}, R², and R³ independently are H or an alkyl group and collectively have from 6 to 30 carbon atoms while forming an unhindered amine.
3) Q is represented by the chemical formula R^{a}—C≡C—, where R^{a} is a hydrogen or an alkyl group with 1 to 8 carbon atoms R^{Q} is an alkyl group with 1 to 8 carbon atoms and X is an OH, or
4) Q is a hydrocarbyl group with one or more alkene groups, 2 to 31 carbon atoms and no heteroatoms, X is OH and R^{Q} is an alkyl group having 1 to 8 carbon atoms.
5) Q is represented by —R⁴NR⁵R⁶, R^{Q} is an alkyl group with 1 to 8 carbon atoms or an aromatic group with 6 to 16 carbon atoms, and X is R³R²NR¹—, where R¹ is a bond or an alkyl group with 1 to 8 carbon atoms, R⁴ is a bond or an alkyl group with 1 to 8 carbon atoms, and R², R³, R⁵, R⁶ are independently H or an alkyl group with 1 to 8 carbon atoms, and
   wherein the additive composition is present at a molar ratio relative to Sn from 0.01 to 10.

In a further aspect, the invention pertains to a method for forming a photo-patternable material comprising water activity modulating additives, absorption modulating additives and/or radical scavenger additives on a wafer, the method comprising:
depositing the enhanced water activity modulating additive, absorption modulating additive and/or radical scavenger additive to achieve an enhanced average concentration of additive within the top 50% of the thickness of the photo-patternable material relative to the average additive concentration through the thickness, wherein the average additive concentration is from about 0.5 wt % to about 35 wt % and the enhanced average concentration is at least about 25% greater than the average concentration, the photo-patternable material comprising organotin moieties represented by RSn, where R is organyl group and forms a carbon tin bond and has from 1 to 31 carbon atoms.

In another aspect, the invention pertains to a coated substrate comprising:
a substrate and
a coating material comprising organotin moieties within a matrix comprising hydroxide ligands and oxo-ligands in an amorphous network and an additive composition, which as added to a precursor composition, is represented by the chemical formula: X—R^{Q}-Q, wherein:
1) Q is a low-polarity hydrocarbyl moiety with optional silicon atom substitution and with optional sulfur atom substitution having from 9 to 31 total carbon, silicon and sulfur atoms and optionally with an aromatic sulfur atom substitution, R^{Q} is an alkyl group with 1 to 8 carbon atoms or a silyl group, and X is H or a polar functional group comprising a heteroatom, or
2) Q is represented by the chemical formula —NR²R³, R² and R³ are independently hydrogen or an alkyl group, X is H and R^{Q}, R², and R³ collectively have from 6 to 30 carbon atoms while forming an unhindered amine or
3) Q is represented by the chemical formula R^{a}—C≡C—, where R^{a} is a hydrogen or an alkyl group with 1 to 8 carbon atoms, R^{Q} is an alkyl group with 1 to 8 carbon atoms and X is an OH, or
4) Q is a hydrocarbyl group with one or more alkene groups, 2 to 31 carbon atoms and no heteroatoms, X is OH and R^{Q} is an alkyl group having 2 to 8 carbon atoms, or
5) Q is represented by R⁵R⁶NR⁴—, R^{Q} is an alkyl group with 1 to 8 carbon atoms or an aromatic group with 6 to 16 carbon atoms, and X is —R¹NR²R³, where R¹ is a bond or an alkyl group with 1 to 8 carbon atoms, R⁴ is an alkyl group with 1 to 8 carbon atoms, and R², R³, R⁵, R⁶ are independently H or an alkyl group with 1 to 8 carbon atoms, and
   wherein the additive composition is present at a molar ratio relative to Sn from 0.05 to 10 and wherein molecules of the additive compositions may or may not be ligated to tin.

### BRIEF DESCRIPTION OF THE DRAWINGS

FIG. 1 is a cartoon depicting the progression of the oligomerization of tin monomers.

FIG. 2 is a cartoon depicting the lithographic patterning of an organotin photoresist coating with ordered polynuclear tin domains.

FIG. 3 is a cartoon depicting the lithographic patterning of an amorphous organotin photoresist coating absent ordered polynuclear tin domains.

FIG. 4 is a simplified representative equilibrium between M-OH, M-L, and M-X bonds in an organometallic photoresist coating.

FIG. 5 is a cartoon depicting a cross-sectional view of an organotin photoresist layer comprising a homogenous distribution of additive and organotin.

FIG. 6 is a cartoon depicting a cross-sectional view of an organotin photoresist layer comprising a negative vertical composition gradient of organotin and additive.

FIG. 7 is a cartoon depicting a cross-sectional view of an organotin photoresist layer comprising a positive vertical composition gradient of organotin and additive.

FIG. 8 is a cartoon depicting the formation of T-topping in lithographic patterned features.

FIG. 9 is a cartoon depicting the formation of footing in lithographic patterned features.

FIG. 10 is a cartoon depicting the lithographic patterning of organotin photoresist coatings comprising vertical composition gradients of additive and organotin.

FIG. 11 is a cross-sectional diagram of WAF-01, as determined by ellipsometry modeling.

### DETAILED DESCRIPTION OF THE INVENTION

Additives selected for improvement of photoresist performance are described that can be incorporated into photoresist films to help control the film formation of the photoresist and reduce variation through the thickness of the film during processing. Metal oxide-based photoresists, such as those based on organotin compositions, represent a promising new class of high-resolution and high-absorbance photoresist materials that are particularly useful for EUV lithography. Organotin photoresist films are generally prepared through hydrolysis of organotin precursors during the deposition process which results in the formation of a radiation-patternable organotin oxide hydroxide film composition. For example, deposition of organotin photoresists via spin-coating generally occurs in ambient conditions wherein the hydrolytically sensitive organotin precursors are hydrolyzed by atmospheric humidity in-situ to form the organotin oxide hydroxide films. The ambient humidity inside wafer fab facilities and wafer processing equipment is generally well-controlled and well-maintained and allows for good reproducibility of hydrolyzed organotin oxide hydroxide films from a given organotin precursor composition. However, while good reproducibility is a desirable outcome, the controlled environment does not allow for adjustment of the conditions to adjust film properties prior to patterning. The incorporation of additives into precursor solutions can result in a disruption of clustering of the tin species such that a more uniform amorphous film can be formed or for non-volatile additives a distribution of additive in the resulting film can influence the post-irradiation film condensation to achieve improved pattern formation. In some embodiments, processing approaches such as deposition of multiple layers can be used to account for stratification through the layer thickness to achieve desired performance from the additives, such as reduction of radiation absorption due to tin dilution in order to achieve a more uniform radiation absorption through the thickness of the coating.

Water activity modulating additives are described to moderate cluster formation which can occur as a result of hydrolysis and/or condensation mechanisms. In some embodiments, water activity modulating additives can be selected to be volatile such that they can be removed prior to irradiation, for example during a post application bake step. In other embodiments, the water activity modulating additives can be selected such that they can be removed after irradiation but prior to development, for example during a post exposure bake step. In still further embodiments, the water modulating additives are effectively non-volatile, and all or most of the additive remains through processing, which is consistent with good patterning if the solubility properties and etch behavior are not negatively impacted. The presence of a water activity modulating additive during the deposition process can provide increased control over the rate or extent of hydrolysis and/or condensation processes that occur rapidly during deposition. The inclusion of these additives can allow for the formation of organotin oxide hydroxide compositions comprising a reduced portion of polynuclear tin ordered domains within a generally amorphous solid film by disrupting the formation of ordered polynuclear tin domains. In some embodiments, the water activity modulating additives can serve a dual function as an absorption profile modifying additive. Absorption profile modifying additives, as dual functional additives, are described to facilitate achievement of a more uniform effective exposure dose through the thickness of the film. Absorption profile modifying additives can generally be retained in the film through the exposure step and have relatively low EUV absorption cross sections. In some embodiments, the inclusion of an absorption profile modifying additives can form a vertical composition gradient of organic material and tin material. In particular, it can be desirable for the additive to have a higher concentration near the top of the film to reduce radiation attenuation. Further additives can be distributed to be concentrated at the bottom of the film to reduce the effects of photoresist-underlayer interactions or radiation reflection off the substrate that can amplify the radiation effects at the bottom of the film.

Organotin precursor compounds represented by the formula RₙSnL₍₄₋ₙ₎ where n=1 or 2 can be suitable organotin compounds for the deposition of radiation patternable photoresist films. Monoalkyl tin precursor compositions can generally be represented by the formula RSnL₃, where R is an organyl group having from 1 to 31 carbon atoms and a radiation-sensitive Sn—C bond and L is a hydrolysable ligand. The organotin compounds can also be referred to as alkyltin compounds and the terms are used interchangeably herein. The use of alkyltin compounds in high performance radiation-based patterning compositions is described, for example, in U.S. Pat. No. 9,310,684 to Meyers et al., entitled “Organometallic Solution Based High Resolution Patterning Compositions,” incorporated herein by reference. Refinements of these organometallic compositions for patterning are described in U.S. Pat. No. 10,642,153 to Meyers et al., entitled “Organometallic Solution Based High Resolution Patterning Compositions and Corresponding Methods,” and 10,228,618 to Meyers et al. (hereinafter the '618 patent), entitled “Organotin Oxide Hydroxide Patterning Compositions, Precursors, and Patterning,” both of which are incorporated herein by reference.

The organotin precursor compounds comprise ligands that can be hydrolyzed with water or other suitable reagents under appropriate conditions to form organotin oxo-hydroxo patterning compositions which can be represented by the formula R_{z}SnO_{(2-(z/2)-(x/2)}(OH)ₓ (where 0<(x+z)<4 and z>0) when fully hydrolyzed. The monoalkyl (z=1) organotin precursor compounds, which have been identified as particularly effective precursors for organotin oxo hydroxo patterning compositions, when fully hydrolyzed can be represented by the formula RSnO_{(1.5-(x/2)}(OH)ₓ where 0<x≤3. It can be convenient to perform the hydrolysis to form the oxo-hydroxo compositions in situ, such as during deposition and/or following initial coating formation. For processing to form radiation patternable coatings, L is generally hydrolysed before or during (e.g., in-situ) deposition to result in a coating comprising a polymeric organotin oxo-hydroxo composition on a substrate wherein the Sn—C bonds remain substantially intact. As a result, a radiation patternable coating having radiation-sensitive Sn—C bonds can be realized.

The R group, alternatively referred to as the organyl ligand, that forms a C—Sn bond generally has from 1 to 31 carbon atoms with 3 to 31 carbon atoms for the secondary-bonded carbon atom and 4 to 31 carbon atoms for the tertiary-bonded carbon atom embodiments, for example, methyl, ethyl, propyl, butyl, propenyl, butenyl, pentenyl, isomers thereof, and branched alkyl. In particular, branched alkyl ligands represented by R¹R²R³C where R¹ and R² are independently an alkyl group with 1-10 carbon atoms, and R³ is hydrogen or an alkyl group with 1-10 carbon atoms. In some embodiments R¹ and R² can form a cyclic alkyl moiety, and R³ may also join the other groups in a cyclic moiety. Suitable branched alkyl ligands can be, for example, isopropyl (R¹ and R² are methyl and R³ is hydrogen), tert-butyl (R¹, R² and R³ are methyl), tert-amyl (R¹ and R² are methyl and R³ is —CHCH₃), sec-butyl (R¹ is methyl, R² is —CHCH₃, and R³ is hydrogen), n-pentyl, sec-pentyl, isopentyl, neopentyl. Examples of suitable cyclic groups include, for example, cyclohexyl, cyclopentyl, cyclobutyl, and cyclopropyl, 1-adamantyl (—C(CH₂)₃(CH)₃(CH₂)₃ or tricyclo(3.3.1.13,7) decane bonded to the metal at a tertiary carbon) and 2-adamantyl (—CH(CH)₂(CH₂)₄(CH)₂(CH₂) or tricyclo(3.3.1.13,7) decane bonded to the metal at a secondary carbon). In other embodiments organyl groups may include aryl, or alkenyl groups, for example benzyl, allyl, or alkynyl groups. In other embodiments the organyl ligand R may include any group consisting solely of C and H, and comprising 1-31 carbon atoms. For example: linear or branched alkyl (ⁱPr, ^{t}Bu, Me, ⁿBu), cyclo-alkyl (cyclo-propyl, cyclo-butyl, cyclo-pentyl), olefinic (alkenyl, aryl, allylic), or alkynyl groups, or combinations thereof. In further embodiments suitable R-groups may include organyl groups substituted with hetero-atom functional groups selected from cyano, thio, silyl, ether, keto, ester, acetal, ketal, or halogenated groups or combinations thereof. In some embodiments, R can be a ligand with one or more carbon atoms optionally substituted with one of more heteroatoms selected from the group consisting of O, S, N, Se, Te, Si, Ge, Sn, F, and I. As generally used in the art, organo, organyl, alkyl and hydrocarbyl can be used interchangeably in reference to ligands without restricting incorporation of unsaturated bonds or heteroatoms.

In some embodiments, R can be an organic ligand comprising an acetal group represented by the formula (OR⁴)(OR³)R²CR¹, wherein R¹ is a substituted or unsubstituted hydrocarbyl group having from 1 to 15 carbon atoms and a Sn—C bond, R² is hydrogen or a substituted or unsubstituted hydrocarbyl group having from 1 to carbon atoms, wherein R³ and R⁴ are independently substituted or unsubstituted hydrocarbyl groups having 1 to 4 carbon atoms or wherein R³ and R⁴ collectively form a bridging structure —OR⁵O—(R⁵═R³+R⁴) where R⁵ is a hydrocarbyl group having 1 to 10 carbon atoms and forms a cyclic linkage between the acetal O atoms. As used presently in the art, acetal refers to either a traditional acetal group or a ketal group. Organotin compositions comprising acetal ligands have previously been disclosed by Applicant in published U.S. Patent Application No. 2025/0074930 to Marwitz, et al. entitled ‘Organotin Compositions Having Ligands With Acetal Functional Groups, Patterning Compositions With Organotin Blends And Positive Tone Patterning’, which is hereby incorporated by reference. The previous results with the acetal group ligands demonstrated desirable positive-tone patterning.

Each R group individually and generally can have from 1 to 31 carbon atoms with 3 to 31 carbon atoms for the group with a secondary-bonded carbon atom and 4 to 31 carbon atoms for the group with a tertiary-bonded carbon atom, optionally with unsaturated or aromatic carbon bonds. Groups with unsaturated carbon bonds and no hetero atoms can be described as a branched or linear group with an overall stoichiometry of CₙH₂₍ₙ₋₁₎₊₃, n=1 to 31. In particular, branched or cyclo alkyl (unsaturated) ligands can be desirable for some patterning compositions. The formation of the oxo-hydroxo coating material can comprise deposition of one or more tin composition(s) with hydrolysable bonds, such as RSnL₃, where L is a hydrolysable ligand, such as an alkoxide (OR′), a dialkyl amine (NR′₂), an acetylide (C≡CR′), or other suitable hydrolysable ligand. Suitable L ligands can include alkylamido or dialkylamido (—NR¹R², where R¹ and R² arc independently hydrocarbon groups with 1-10 carbon atoms or hydrogen), siloxo (—OSiR¹R²R³, where R¹, R², and R³ are independently hydrocarbon groups with 1-10 carbon atoms), silylamido (—N(SiR¹₃) (R²), where R¹ and R² are independently hydrocarbon groups with 1-10 carbon atoms), disilylamido (—N(SiR¹₃) (SiR²₃) where R¹ and R² are independently hydrocarbon groups with 1-10 carbon atoms), alkoxo and aryloxo (—OR, where R is an alkyl or aryl group with 1-11 carbon atoms), azido (—N₃), alkynido (—C═CR, where R is a hydrocarbon group with 1-9 carbon atoms), amidato (—NR¹(COR²) where R¹ and R² are independently hydrocarbon groups with 1-7 carbon atoms or hydrogen), amidinato (—NR¹C (NR²) R³) where R1, R2, and R³ are independently hydrocarbon groups with 1-8 carbon atoms or hydrogen), imido (—N(COR¹) (COR²), where R¹ and R² are independently hydrocarbon groups with 1-8 carbon atoms or hydrogen), or fluorinated analogues thereof. The hydrolysable ligands can be hydrolyzed to form the oxo-hydroxo network during deposition of the coating and/or in the coating following deposition, i.e., completing the hydrolysis after deposition. Applicant has developed methodologies to efficiently and effectively form a wide range of patterning compositions with different R groups, optionally with various hetero atoms, with C—Sn bonds, as described further in published U.S. patent application No. 202200064192 to Edson et al. (herein the '192 application), entitled “Methods to Produce Organotin Compositions With Convenient Ligand Providing Reactants,” incorporated herein by reference.

Processing of the organotin precursor compositions to afford organotin oxo-hydroxo coatings generally involves hydrolysis of the RSnL₃ composition(s) to afford the related organotin oxo-hydroxo composition(s). Hydrolysis can be performed prior to the deposition process to yield soluble organotin oxo-hydroxo species (i.e., clusters, oligomeric species, etc.) These soluble organotin oxo-hydroxo species can then be dissolved and/or dispersed into a suitable solvent to form an organotin photoresist solution that can then be used to form radiation-patternable organotin oxo-hydroxo coatings. Alternatively, the organotin precursor compositions can be directly dissolved in a suitable solvent to form a photoresist solution that can then be used to form radiation-patternable organotin oxo-hydroxo coatings. The organotin precursor compositions can also be hydrolyzed in-situ with water during the substrate coating process, such as during vapor deposition, and/or during post coating processing, generally prior to irradiation for patterning. Various processing options are described further in the '684 and '618 patents referenced above.

While not wanting to be limited by theory, during the formation of an organometallic photoresist film, the film can generally be thought of as three non-distinct regimes. In a first regime (I), the as-deposited organotin precursor compound is solubilized in a liquid phase, which is generally an organic solvent. Upon application, the liquid phase and dissolved organotin precursor generally exhibit Newtonian fluid-like behavior and the spread of the film into an initial flat, uniform layer using spin coating results from the centrifugal force of the spinning, and thinning of the film is primarily driven by the liquid being mechanically removed from the substrate via centrifugal force. In the second regime (II), evaporation of the solvent can occur, and the organotin compounds can react with ambient species to initiate the formation of an amorphous organotin oxo hydroxo network. The initial formation of the organotin oxo hydroxo network is believed to initiate with the hydrolysis of hydrolysable ligands to generate —OH bonds which can further condense to form Sn—O—Sn linkages. As bonds are formed within the amorphous network and liquid phase solvent is evaporated, the film can be in a gel phase where the organotin oxo hydroxo network provides mechanical rigidity to the film, and entrains some solvent within. In a third regime (III), further spinning, blowing, and/or thermal energy in a post application bake (PAB) can evaporate substantially all of the solvent and/or form new bonds and the film can be a rigid solid-state film. During this stage, modification, e.g., densification of the film is primarily driven by the evaporation of solvent and/or hydrolysis of hydrolysable ligands. In this regime, the transition from a gel phase to a solid film is generally thought to be complete when solvent is substantially removed from the film. Since hydrolysis of hydrolysable ligands generally results in release of a molecule essentially indistinguishable from a solvent molecule, the release of retained solvent can be due to freeing of weakly bound solvent or release of molecules resulting from hydrolysis with essentially indistinguishable outgassing. This outgassing can be determined by any suitable method in the art, for example thermal desorption gas chromatography/mass spectrometry (TD GCMS) or thermogravimetric analysis (TGA). The delineation of three regimes is intended to be an illustrative framework to conceptualize the chemical and physical transformations occurring during the spin coating deposition of an organometallic photoresist film. The regimes may not be distinct or sequential, transitions between phases can be overlapping or gradual, and aspects of some regimes can even occur simultaneously.

For organotin photoresist compositions wherein the organotin precursor(s) are dissolved into a solvent for spin-coating or similar solution-based deposition methods, organotin trialkoxides (triorganooxides) (RSnL₃, L═OR′, where R′ is an organo group with at least one C atom, optional heteroatoms and optional unsaturated groups) can be desirable for use. Some advantages to organotin trialkoxide compositions are, for example, the production of benign side-products, e.g., alcohols, that are relatively innocuous compared to the production of other reaction products (e.g., amines) which may cause contamination concerns, environmental health and safety concerns, and/or similar issues within the wafer track and/or wafer fab. While organotin triamides can be useful as precursors in vapor-based deposition methods (such as described in the '618 patent), organotin trialkoxides also possess appreciable vapor pressures and low melting points which also makes them attractive compounds for use in vapor deposition methods to prepare radiation-patternable coatings. In any case, the choice of organotin precursors used to produce radiation-patternable organotin oxide hydroxide films can be largely driven by processing considerations and/or limitations.

For deposition of organotin oxide hydroxide films via spin-coating, the hydrolysis of RSnL₃ compounds generally occurs during the spin-coating process (i.e., in-situ hydrolysis) due to the presence of moisture in the ambient environment, although completion of the hydrolysis may occur following completion of the coating process, such as during a post application bake. In the spin-coating process, an aliquot of an organotin photoresist solution is deposited onto the surface of a substrate (e.g., a silicon wafer) which is then rotated rapidly. The rapid rotation causes the photoresist solution to spread evenly across the surface of the wafer which dramatically increases the surface area to volume ratio of the photoresist solution. Rapid solvent evaporation occurs alongside hydrolysis/condensation processes as the organotin compositions react with water vapor to result in the transition of the photoresist solution into a gel-like film and eventually into a solid film. While the evaporation of solvent during spin coating is beneficial, it is desirable for certain compounds such as water activity and absorption profile modifying additives to remain, at least to a desired concentration, in the gel-like film post spin coating. The additive composition and additive concentration can be selected accordingly. The evolution of the gel-like film phase into the solid film phase can be influenced by the composition of the photoresist material, and the presence of certain compounds can effectively modulate the hydrolysis and condensation processes that occur during the phase transition. Modulation of these hydrolysis and condensation processes can be useful to tailor the properties of the resulting photoresist film. As explained further in the following, it is desirable to inhibit excessive clustering of organotin moieties during the completion of the oxo-hydroxo network formation such that a more uniform amorphous film is formed. During solid film formation, domains can develop based on structures mimicking solution phase species or clusters that can form due to hydrolysis and condensation in solution. These structured domains can result in inhomogeneities in the solid film that disrupt an otherwise uniform, amorphous oxo-hydroxo network of the organotin moieties.

While not wanting to be limited by theory, one property of the resulting photoresist film that is believed to affect the lithographic performance of the film is the speciation of polynuclear tin species therein. In other words, the distribution of various polynuclear tin domains within the organotin oxide hydroxide film is believed to play a role in the ultimate patterning performance of the resist coating, and this distribution of species can be modified by the presence of coating modifier additive compounds described herein. During the in situ hydrolyzation of hydrolysable ligands, L, polynuclear tin species, such as clusters and oligomers, can be formed through hydrolysis and condensation reactions, and the ultimate distribution of hydrolyzed and condensed products can depend on various reaction conditions, such as the concentration of water, the identity of the organotin precursors, the identity of the hydrolysable ligands, the temperature of the reactions, and so forth. Polynuclear tin species in solution may comprise as little as two tin atoms (e.g., dimers), and structures containing 12 tin atoms (e.g., dodecamers) are known to readily form as a result of thermodynamic favorability. These structures have been studied by Applicant and others, such as described in U.S. Pat. No. 12,071,449 to Cardineau, et al., entitled “Tin dodecamers and radiation patternable coatings with strong EUV absorption”, hereinafter referred to as the '449 patent, and in published U.S. Patent Application No. 2023/0112618 by Kenane et al. entitled “Tin-base photoresist composition and method of making”, both of which are hereby incorporated by reference. Clusters that form prior to establishing the dry film can result in ordered domains embedded within an otherwise amorphous matrix, which can result in non-uniformities. The inhibition of clustering during deposition is directed to improving pattern properties. Modulating the amount of water in the film through the addition of certain compounds or diminishing the ability of water to hydrolyze the hydrolysable ligands can effectively tune the activity of hydrolysis and condensation processes that occur therein. This modulation of the hydrolysis can be advantageous for reducing film inhomogeneities to achieve improved pattern fidelity after development as well as forming a film capable of producing repeatable patterning results amidst changes in processing environment humidity, which may not be controlled to a desired degree within process chambers within a semiconductor processing facility. While not wanting to be limited by theory, it is believed that the hydrolysis of hydrolysable ligands, L, and the formation of a network of tin species bonded through tin-oxo and tin-hydroxo linkages proceeds through hydrolysis and condensation pathways represented by the reaction schemes:

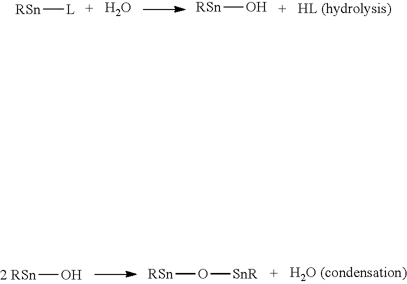

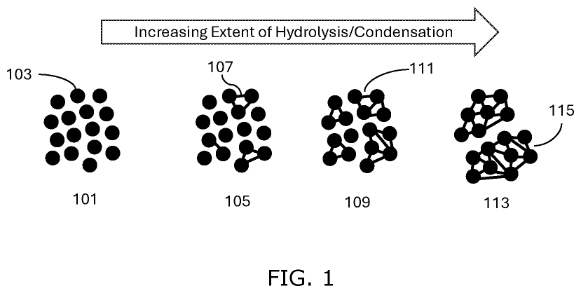

Higher water activity can generally favor the hydrolysis reaction and, in principle, disfavors the condensation reaction. While not wanting to be limited by theory, experience suggests that water facilitates condensation, and free energy reduction may not be as straightforward as suggested by the simple reactions. Thus, while driving off water may be involved in forming a fully condensed oxide, water may not be inhibitory of forming a relatively condensed material since it facilitates the formation of Sn—OH moieties. Effective completion of the hydrolysis reaction and at least some condensation is believed to be involved in forming a uniform stable solid film for irradiation with an oxo-hydroxo network within an effectively amorphous material. The removal of solvent may further favor condensation that is limited by the organyl ligands to tin ions. However, excessive condensation during hydrolysis can generally give rise to high nuclearity tin species, such as dodecamers, that rapidly become more concentrated as solvent evaporate and that can form as a result of their thermodynamic stability in solution that carries over into ordered domains in the solid film. High nuclearity clusters can be prone to precipitation both in solution and on wafer during deposition and coating, which can generally contributes to the formation of unfavorable films with respect to uniformity and performance. The progression of tin oligomerization through these pathways is schematically depicted in FIG. 1. Precursor composition 101 comprises organotin monomers 103. As hydrolysis and condensation pathways proceed, partially condensed organotin composition 105 comprising tin-oxo bonds 107 forms. Continued progression of hydrolysis and condensation pathways may form a condensed organotin composition 109 comprising ordered tin domains 111, and ultimately a dried film comprising the organotin composition 113 comprising an organotin material 115 is formed with a degree of order and inhomogeneity reflecting the processing and compositions.

In the context of high-resolution lithography processes where generating nanoscale patterns is the objective, high nuclearity structured domains can limit the resolvable feature size that can be repeatedly produced without defects. In this way, the organotin ordered domains can be likened to pixels in a digital image, such that larger pixels reduce the overall resolution and detail of an image. As the feature size approaches the dimensions of larger organotin ordered domains, defects may become more prevalent, leading to degradation in pattern fidelity and resolution. The organotin oxo-hydroxo nano-structures can be likened to pixels, such that the size of the networks influences the feature size that can be produced repeatably without exceeding defectivity thresholds. In some embodiments, a stabilizing additive can facilitate the formation of a solidified tin network in a controlled manner with greater amorphous character. In any aspect, improved control of the speciation is desirable to tune the photoresist properties for versatility in application and processing conditions.

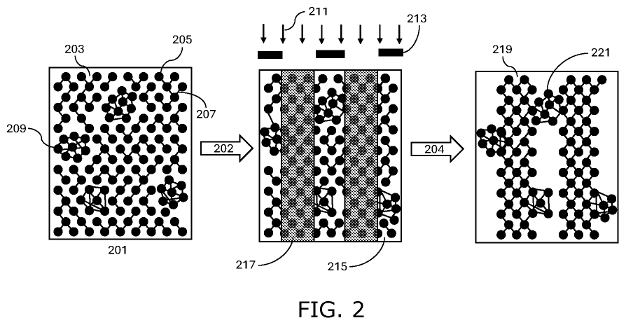

FIG. 2 depicts the formation and lithographic impact of high-nuclearity tin ordered domains. Deposited organotin coating 201 consists of an amorphous tin oxo-hydroxo network 203 comprising organotin moieties 205 bridged to one another through oxo bonds 207 along with hydrogen bonded hydroxyl groups and embedded highly ordered organotin domains 209 with high oxo-bond density. During exposure step 202, radiation source 211 is directed onto the organotin coating through photomask 213, generating unexposed regions 215 and exposed regions 217 having increased oxo-bond density. In negative-tone development step 204, the unexposed regions are preferentially removed although high nuclearity tin nano-structures in the unexposed regions may remain. The resulting negative tone pattern 219 can exhibit relatively poor edge roughness and bridging defect 221, and such bridging defects can produce deleterious effects on the integrated circuit devices within which they are incorporated.

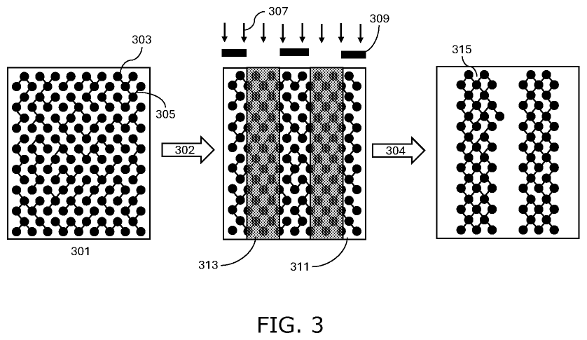

FIG. 3 schematically depicts the improved lithographic patterning of an amorphous organotin photoresist coating with a reduced amount of ordered tin domains. Deposited amorphous organotin coating 301 comprises organotin species 303 bridged to one another through oxo bonds 305 with high uniformity and low medium-range order. In exposure step 302, radiation source 307 is directed on to the organotin coating through photomask 309, generating unexposed regions 311 and exposed regions 313 with increased oxo-bond density and reduced organic loading. During subsequent development step 304, the unexposed regions are preferentially removed and the resulting negative tone pattern 315 exhibits excellent edge roughness and closely corresponds to the exposed regions.

The distribution of organotin species in the film can be modulated by the inclusion of coating modifier additives that can influence the evolution of the hydrolysis and condensation processes during deposition, and in some embodiments, may influence radiation attenuation profile through the coating thickness. One class of effective coating modifier additives, which can also be referred to as water activity modulating additives, are generally compounds that are hydrophobic in nature. The integration of such compounds into the film can impart hydrophobic properties to the bulk film and significantly reduce the surface energy of the film as a whole. The reduced surface energy reduces the affinity between the film and atmospheric water, which can reduce the extent and/or rate of hydrolysis and condensation reactions. Accordingly, hydrolysis and condensation reactions can be more limited due to a lower amount of available water compared to films prepared without additives. As noted above, the hydrolysis and condensation reactions should progress to an appropriate degree to prepare the film for patterning, the inclusion of a water activity modulating additive provides desirable adjustment capability to tune the water activity to form a desired film quality that balances the various reactions. Careful selection of additive species with varied water affinities, along with precise control of their concentrations, can fine tune condensation and hydrolysis reactions during formation of the film by reducing the formation of high nuclearity tin species during film formation to reduce ordered domains in the solid film, thus realizing improved patterning performance. As demonstrated herein, coating modifier additives may stratify within the coating layer during a spin coating process, and processing can be adjusted accordingly.

The hydrophobicity of the additives can generally be quantified by the octanol-water partition coefficient, P, and which is typically expressed as a log base-10 value, log(P). Higher octanol-water partition coefficients correspond to more hydrophobic compounds. The octanol-water partition coefficient of a compound measures the relative lipophilicity of the compound in a biphasic system of 1-octanol and water. After the compound has reached equilibrium in a biphasic system of 1-octanol and water, the partition coefficient is calculated as the concentration of the compound in n-octanol divided by the concentration of the compound in water. Numerous software programs are available to calculate a theoretical value of log(P), termed c log(P), such as those from BioByte and Chemdraw, and various models have been proposed to effectively calculate the value such as Crippen and Wildman's 1999 publication “Predication of Physiochemical Parameters by Atomic Contributions”, which is herein incorporated by reference. Additionally, log(P) coefficients of numerous compounds have been determined and compiled in databases such as Dortmund Data Bank's Octanol-Water Partition coefficient (POWDDB) database, which is hereby incorporated by reference. While the non-aqueous solvent generally comprises a polar compound, the solubility of an additive in a precursor solution may or may not correlate significantly with the log(P) value.

It is hereby noted that calculated log(P) values may vary from experimentally determined values or log(P) values calculated using one established mathematical model may differ from log(P) values for the same compound calculated using a different established mathematical model. The calculated log(P) value for a compound may differ from an experimentally determined value or another calculated value by up to 20% in certain cases, up to 10% in others, and up to 5% in some instances. To ensure clarity and consistency, for the scope of this disclosure all log(P) values refer to the octanol-water c log(P) values calculated using the BioByte software. The BioByte method has been accepted as the gold standard in partition coefficient calculation across various arts for decades and, for compounds presently of interest, generally produces results in strong agreement with experimental values. Mathematically calculated values of log(P) for common hydrocarbons calculated using BioByte are given in the table below for reference.

| Compound | c log(P) |
|---|---|
| Benzene | 2.13 |
| Toluene | 2.73 |
| p-xylene | 3.14 |
| Naphthalene | 3.34 |
| Cyclohexane | 3.44 |
| Pentane | 3.45 |
| Anthracene | 4.56 |
| Adamantane | 5.02 |
| Pyrene | 5.08 |
| Triphenylene | 5.49 |
| Nonane | 5.65 |

Water activity modulating additives can be incorporated into the resist composition at various stages to ensure flexibility and applicability through varying lithographic conditions and processes. In some embodiments the additive can be mixed with a precursor solution prior to deposition. In other embodiments the compound can be deposited onto a substrate before, after, or simultaneous to organotin precursor deposition. Viable methods of depositing the additives include spin coating, chemical vapor deposition, atomic layer deposition, or any other suitable deposition method known in the art. In some embodiments, regardless of the application approach, additive deposition is performed prior to a post application bake step, if used. In view of stratified concentrations following spin coating, a desired distribution of additive concentration relative to the top of the photo-patternable coating can be more closely achieved using multiple coating layers. There may or may not be a post application bake step after a particular deposition step. The boiling point of an additive can be considered during additive selection such that a sufficient additive is present at a process step of interest.

As noted above, a water activity modulating additive can stratify in the resist composition during the deposition process, such as during spin coating. The resulting distribution can be complex and depend on the nature of the additive and the parameters of the deposition process, such as the spin coating profile. In particular, there can be an enhanced concentration of additive toward the top of the resist layer, toward the bottom of the resist layer, or both. In the examples, additives are observed to have enhanced concentrations near the bottom of the layer or in a bifurcated distribution with enhanced concentrations near the bottom of the resist layer with a concentration also near the top of the resist. By-layer stratification from spin-coating is known.

In principle, a by-layer stratification of an additive can be desirable. Due to intensity attenuation through the resist as radiation is absorbed, the radiation receiving surface tends to undergo increased or more rapid condensation and Sn—C bond cleavage relative to material deeper into the resist, which can result in T-topping upon development, which corresponds to edges in a developed structure that are not planar. At the bottom of the structure at the substrate, the radiation can reflect from the substrate. While in principle, the reflection may diminish the attenuation effect due to absorption by the upper strata, an inverse result from attenuation from the bottom can result in an increased condensation at the bottom of the resist relative to intermediate layers that can result in a footer effect, i.e., increased condensation and hydrolysis along the substrate surface. Interfacial interactions between the photoresist and any underlayer may similarly result in a bottom resist layer with an increased developer resistance relative to the top of the photoresist later, which may result in footing. An additive can both decrease attenuation by dilution with a low absorbing component and slow or decrease condensation to reduce formation of ordered domains by disrupting the condensation process. While a natural bifurcated or graduated distributions can be achieved with spin coating, these can in some embodiments have a relatively greater amount at the bottom of the material, while the desire to address effects of stratification suggests a desire for a greater concentration near the top of the layer toward the radiation receiving surface. For some additives, to achieve a distribution closer to a target for reducing a larger T-topping issue, multiple deposition steps can be used.

A spin coating process can be complex with respect to the nature of the spin coated product. While the additives generally are sufficiently soluble in the organotin composition such that the spin coated product does not phase separate, the resulting distribution of additive through the layer of organotin composition may not be uniform. The nature of the non-uniformity can be strongly dependent on the nature of the additive. In the exemplified evaluation, a pure organotin layer was formed along the top of the coating and in some embodiments along the bottom of the coating. The intermediate region of the coating had a gradient of additive with a higher concentration of additive at the bottom of the gradient. This distribution would not provide a more uniform absorption of radiation through the thickness of the coating nor would it slow hydrolysis at the top of the coating which is more accessible to water. While this observed stratification may be, in some sense, opposite of a target distribution, the use of multiple layers can adjust for this and take advantage of this result to some degree, since this distribution may naturally address some footer issues based on the higher concentration of additive toward the bottom of the gradient and since some embodiments can avoid the presence of a pure organotin material at the bottom of the coating.

The introduction of a higher additive concentration toward the top of the coating can be accomplished through the deposition of one or more additional layers. The further coating processes have several parameters that determine the effects of the additional layer: status of the initial layer (for example, gel, dry, baked, or any partial or intermediate states), composition of the subsequent coating material (for example, organic solvents, solutions of additives, organotin precursors, additional additives, another suitable coating composition, or combinations thereof, as well as concentrations), the amount of the subsequent coating material, and post processing after a subsequent coating step. If the additive can diffuse into the organotin layer, it can be appropriate to deposit a solution of additive that can then diffuse into the patternable coating to dilute the top of the organotin material to achieve a more uniform effect of the radiation through the coating thickness. If a second layer of organotin composition with additive is deposited over the initial layer, this layer may or may not interpenetrate with the underlayer during processing. If there is interpenetration, the additive concentration at the top of the organotin underlayer can be increased if the additive is the same, or a total additive concentration can be increased if the second additive is different from the first additive. The additive distribution in the subsequent additive coating of organotin material may itself be non-uniform depending on coating parameters. It may be desirable to use a particularly thin subsequent coating and/or a thin preliminary coating below a main coating to reduce effects of stratification in a subsequent organotin coating. A subsequent dried coating may be from about 1 nm to about 15 nm and in some embodiments from about 1.5 nm to about 12 nm and in further embodiments from about 2 nm to about 10 nm, although a subsequent (or preliminary) coating could have a thickness comparable to an initial coating with corresponding thickness ranges. A person of ordinary skill in the art will recognize that additional ranges of subsequent coating thicknesses within the explicit ranges above are contemplated and are within the present disclosure.

While the exemplified additive stratifies upon spin coating with reduced concentrations of additive near the top of the coating, other additives can stratify with an increased concentration of additive near the top of the coating. Such distributions may directly form a desired additive distribution, although it would be a desirable distribution if a top layer of organotin oxo-hydroxo material is not formed. The desire for one or more subsequent coating layers can be based on the observed stratification of additive in an initial coating. As suggested above, a plurality of additives may be used. In particular, in some embodiments, a first additive can be introduced in an organotin coating while a second, different additive can be introduced in a subsequent coating. The option of using two or more coating layers with additives provides considerable flexibility to achieve a desired distribution of additives to engineer the patterning performance.

Selection of a water activity modulating additive implicates a few factors. To perform the function of modulating water activity, the log(P) value should be desirably high. On the other hand, the additive should be appropriately soluble in the solvent, which can be a blend. As described further below, an additive should also have a low enough volatility that it is not completely removed from the deposited patterning film prior to completion of the hydrolysis, so the additive boiling point is generally greater than the boiling point of the solvent by a significant degree. Desirable factors of log(P) for additives can be at least about 3.0, in further embodiments, at least about 3.25, in some embodiments from about 3.5 to about 18.0, and in other embodiments the range of log(P) from about 3.75 to about 16.0. A person of ordinary skill in the art will recognize that additional ranges of log(P) within the explicit ranges above are contemplated and are within the present disclosure.

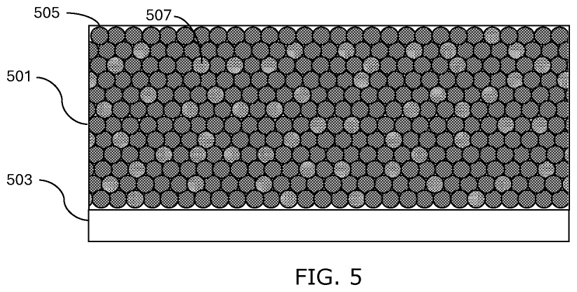

In films without additives, water can dissolve in the film to varying degrees during processing. This water can be beneficial with respect to completing the hydrolysis of the precursors, but excess water activity can result in high nuclearity structure associated with clustering of the tin atoms within the solid film, which can lead to inhomogeneity, as described above. In some embodiments, the additive enhanced organotin precursor solution is deposited to form a film wherein the additive is distributed homogenously throughout the film, as depicted in FIG. 5 wherein film 501 overlying substrate 503 comprises a homogenous distribution of organotin moieties 505 and additive moieties 507 through the vertical height of the film. As a whole, the resulting film has increased hydrophobicity and can exhibit a reduced amount of condensation and/or hydrolysis reactions. Accordingly, a distribution of organotin species having a lower average nuclearity compared to a non-additive enhanced film can be realized. Such a distribution of the additive in the film presumes that the additive is soluble in the amorphous organotin matrix such that the additive does not phase separate during the deposition process as solvent is removed and that the additive has suitable properties with respect to response to spin coating, that the additive does not stratify within the layer due to complex forces exhibited during spin coating. Some additives may exhibit his behavior, while others do not. The use of a plurality of coating layers sequentially deposited provides some added ability to influence the distribution of additive within the coating. Sequential depositions can be used in the context of either water activity modulating additives, absorption modulating additives and/or radical scavenger additives. As used herein, the term stratification refers to the formation of graded layers, discrete layers, or the formation of discrete layers separated or combined into graded layers.

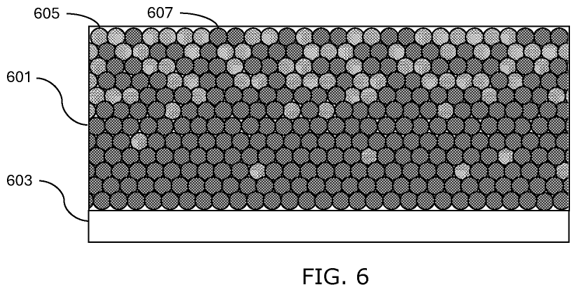

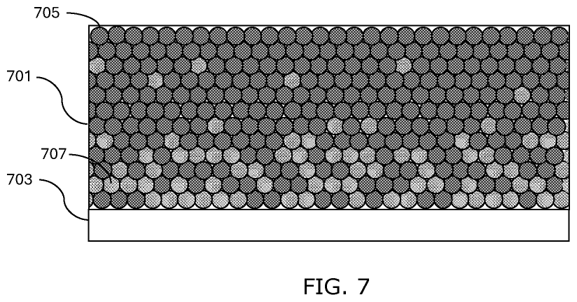

In some embodiments, due to complex effects of spin coating, the water activity modulating additives can form a vertical composition gradient, orthogonal to the substrate surface, with the organotin compositions. In some embodiments, the vertical composition gradient can comprise a graduated concentration of organotin moieties that decreases from the bottom of the film, which contacts the substrate, to the top of the film, opposite the substrate. This is depicted in FIG. 6 wherein photoresist film 601 overlying substrate 603 comprises organotin moieties 605 and additive moieties 607 wherein the concentration of organotin moieties decreases from the bottom of the film to the top of the film (negative gradient). In some embodiments, the vertical composition gradient comprises a graduated concentration of organotin moieties that increases from the bottom of the film to the top of the film. This is depicted in FIG. 7 wherein film 701 overlying substrate 703 comprises organotin moieties 705 and additive moieties 707 wherein the concentration of organotin moieties increases from the bottom of the film to the top of the film (positive gradient). While not wanting to be limited by theory, it is believed that the vertical composition gradient can form naturally from the polarity difference, and potentially other differences, between an additive and the organotin material, so if the solvent removal allows for adjustments of the less dense additive relative to the organotin composition some stratification may occur naturally. The degree of stratification (i.e. intensity of the compositional gradient) can depend on the additive compositions, organotin compositions, thermal processing conditions, and deposition parameters. In some embodiments, the deposited organotin photoresist films can comprise different combinations of two or more discrete graduated organotin-additive and organotin layers. Reports of stratification of additives in organic photoresists resulting from spin coating suggest complex effects from the coating dynamics, which may not directly carry over to the organotin processing except to the extent of confirming the complexity of the process awaiting further elucidation.

While not wanting to be limited by theory, it is believed that a polarity difference, and potentially other differences, between organotin compositions and organic additives can drive the stratification and formation of the vertical composition gradients described. The vertical composition gradients comprising organic additive and organotin composition can be detected and characterized through ellipsometry, as exemplified herein. The difference between the c log(P) values of both species is believed to correlate to the intensity of the compositional gradient. For negative gradients, the additive concentration can be greater in an upper portion of the thickness of the photoresist. For example, the additive concentration can be greater in the upper 50% of the thickness in some embodiments, in the upper 35% of the thickness in other embodiments, and in the upper 20% of the thickness in further embodiments. For positive gradients, the additive concentration can be greater in a lower portion of the thickness of the photoresist. For example, the additive concentration can be greater in the lower 50% of the thickness in some embodiments, in the lower 35% of the thickness in other embodiments, and in the lower 20% of the thickness in further embodiments. The greater concentration in the identified portion of the photoresist can be quantified relative to the average additive concentration across the full thickness of the photoresist layer. In some embodiments, the additive concentration in the identified portion is at least 5% greater than the average additive concentration across the full thickness, in other embodiments at least 10% greater, and in further embodiments at least 25% greater. If there are discrete layers, each discrete layer may be distinguished from other layers by a change in composition and/or by a change in gradient direction, such as a change from a decreasing concentration gradient to a greater concentration value, which may then resume its a new gradient or then maintain an approximate constant concentration over the discrete layer. The above gradient distinctions can be directed to a discrete layer or to the overall coating as indicated in a particular embodiment. A person of ordinary skill in the art will recognize that additional ranges of concentration gradients within the explicit ranges above are contemplated and are within the present disclosure.

In some embodiments, the compositional gradient can form during deposition processes due to the polarity difference between the additive and organotin species. In some embodiments, it can be desirable for the water activity modulating additives to be removed from the film prior to irradiation. The water activity modulating additives are generally not photosensitive and have a low EUV absorbance cross section relative to organotin. On the other hand, if a gradient of the additive is intended to improve the radiation absorption uniformity through the coating thickness, then at least some of the additive is intended to remain at the time of irradiation. Appropriate additives to be removed can be conveniently evacuated from the film during a baking step, if not removed during coating, prior to irradiation such as a post application bake (PAB). The temperature of a PAB can be from about 45° C. to about 250° C. and the duration can be from about 30 seconds to about 30 minutes. The temperature and duration of the PAB can be carefully selected to ensure the additive is sufficiently volatilized and evacuated from the film, and the atmosphere above the film during the PAB may be selected to facilitate this, such as a reduced pressure. A person of ordinary skill in the art will realize that additional PAB durations and temperatures within the explicitly cited ranges above are contemplated and within the scope of the present disclosure.

The boiling point or decomposition temperature of water activity modulating additives is a significant parameter that generally is taken into account when properly selecting an additive that can substantially remain in the film post spin coating and, if desired, can be evacuated from the film during a PAB. Some additives may be effectively removed during spin coating, but slower than the solvent, such that a water activity modulating additive can be effective even if not maintained for further processing. Similarly, if the water activity modulating additive is to be kept in the film during irradiation to function possibly as an absorption modulating additive, a dual function additive, the boiling point may be selected appropriately higher. In some embodiments, the boiling point or decomposition temperature of the additive should be sufficiently high to substantially remain in the film post spin coating, which is in contrast to the boiling point of organic solvents which are generally sufficiently low to where a significant portion of the solvent is evaporated during spin coating. Although the boiling point of the neat additive may or may not correspond to the exact temperature at which the additive will be removed from the film during a PAB, it can serve as a useful proxy for estimating its volatility during thermal processing. In some embodiments in which the water activity modulating agent is removed prior to irradiation, the water activity modulating additives have a boiling point between about 100° C. and about 300° C., while in other embodiments the boiling point of the additives is between about 125° C. and about 250° C., and between about 140° C. and 225° C. in further embodiments. In addition to the absolute boiling point value, the additive generally has a boiling point that is at least about 10° C. greater than the solvent, in further embodiments at least about 15° C., and in other embodiments at least about 20° C. greater than the solvent. In some embodiments, the additive is intended to remain in the film potentially through development and possibly further processing. For these persistent additives, they may not have a boiling point and may decompose prior to evaporating, but in some embodiments, they have a boiling point of at least about 250° C., in some embodiment at least about 300° C. and in further embodiments at least about 325° C. A person of ordinary skill in the art will realize that additional temperature ranges and values within the explicit ranges above are contemplated and are within the scope of the present disclosure.

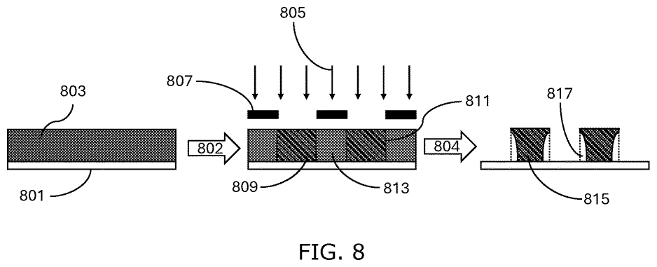

In some embodiments, the formation of a vertical composition gradient may provide an added functionality as an absorption profile tuning additive, although the gradient can also facilitate modulating water activity. The added functionality of an absorption profile tuning additive may be realized when the additive is incorporated in the film and present during irradiation. The vertical composition gradients can be effective for correcting different cross sectional resist profiles. Specifically, when using EUV radiation, it is observed that EUV photon absorption occurs more efficiently at the top of the film, opposite the substrate, relative to the bottom of the film, contacting the substrate. As used herein, the term nominal dose refers to the radiation fluence delivered to the photoresist film from the exposure tool, and the term effective dose refers to the radiation dose present at a specified vertical position within the film. In an idealized exposure condition, the effective dose at each vertical height is equal to the nominal dose and this uniform dose profile would in theory yield vertical sidewalls in cross sectional resist profiles. Differences between the nominal dose and the effective dose can arise from absorption related phenomena, can physically manifest as tapered cross sectional feature profiles, which can be corrected through the addition of absorption profile modifying additives. The high EUV absorbance of tin results in photons being absorbed efficiently near the top of the resist film which results in less photons being available near the bottom of the film, termed dose attenuation, which then is convoluted with the effective dose distribution. While not wanting to be limited by theory, it is believed that vertical dose variations are due to attenuation of the incident radiation through the depth of the film. Dose attenuation throughout the depth of the film can have undesirable effects on patterning performance due to the formation of patterning features with negative tapered cross-sectional profiles, also referred to as T-topping in the art, depicted in FIG. 8.

Referring to FIG. 8, substrate 801 supports organotin photoresist film 803. In irradiation step 802, radiation source 805, is directed through photomask 807, which can be a physical mask or mechanism for directing radiation 805, to form exposed regions 809 within projected image boundaries 811 and unexposed regions 813. Development step 804 forms a physical pattern with T-topped patterned features 815, having tapered cross-sectional profiles. The cross-sectional profile results from the removal of insufficiently irradiated regions 817 which manifest as a physical discrepancy between patterned features 815 and the projected image boundaries.

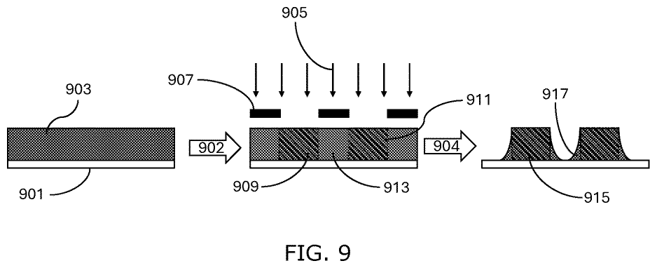

In some embodiments, patterned photoresist features can exhibit footing wherein the width of the feature increases near the resist-substrate interface. While not wanting to be limited by theory it is believed that footing can arise from the reflection of incident radiation by the substrate or layers underlying the photoresist film. Reflected radiation can produce an elevated local exposure dose at the bottom portion of the photoresist film relative to the top portion of the photoresist film. The non-uniform effective dose profile can result in under-development at the base of the patterned features, thereby producing a feature having a wider base than intended. In some embodiments, footing of patterned features may additionally or alternatively arise from developer transport mechanics, resist-underlayer interactions, or combinations thereof. In this case, the absorption profile modifying additives can reduce the effective exposure dose delivered to the bottom region of the photoresist film which can counteract these effects to produce patterned features with more vertical cross sectional profiles and improved feature to feature uniformity at the resist-underlayer interface. The formation of patterned features exhibiting footing is depicted in FIG. 9 wherein substrate 901 supports organotin photoresist film 903. In exposure step 902, radiation source 905 is directed through photomask 907, which can be a physical mask of a mechanism for directing radiation, to form exposed regions 909 within projected image boundaries 911 and unexposed regions 913. Development step 904 forms a physical pattern comprising footed patterned features 915, which are characterized by residual material 917 outside of the projected image boundaries.

Patterning features with tapered cross-sectional profiles are known to cause undesirable variations in resolution, critical dimension, sidewall angle and additionally contribute to pattern collapse, ‘T-topping’, and ‘footing’. The tapered cross-sectional profiles can also produce overcut or undercut etch profiles during subsequent etch transfer steps. During exposure, EUV photons lose energy due to absorption as they propagate through the depth of the film, such that the actual dose received throughout the depth of the film is different from the applied dose and decreases with increasing film depth.

With an appropriately selected additive profile, the resulting gradient of organotin composition and absorption profile modifying additive can be designed for approximating a coinciding effective EUV absorption gradient. The organotin compositions are known to be efficient EUV photon absorbers due to tin's high EUV absorption cross-section, while the organic, non-metal containing additives are less efficient due to the low EUV absorption cross-section of organic elements such as Si, S, C, H, O, and N. While not wanting to be limited by theory, it is believed that the EUV absorption gradient of the film is adjusted to reflect these properties, such that EUV photons are absorbed more uniformly through the depth of the film as radiation propagates through the depth of the film. The manipulated absorption profile of the film can effectively offset or partially offset the vertical dose variations that may arise from attenuation, reflection, or other optical phenomena. When the resist composition incorporates an absorption profile modifying additive, the resulting effective dose is generally more uniform throughout the depth of the resist. Absorption profile modifying additive generally remains in the film in appropriate amounts at the time of irradiation. The distribution of the additive can be adjusted as described above based on spin coating profiles and possibly the use of multiple coating layers. With an appropriately formed profile through the film thickness, it may be possible to address a T-topping issue as well as a footer issue.

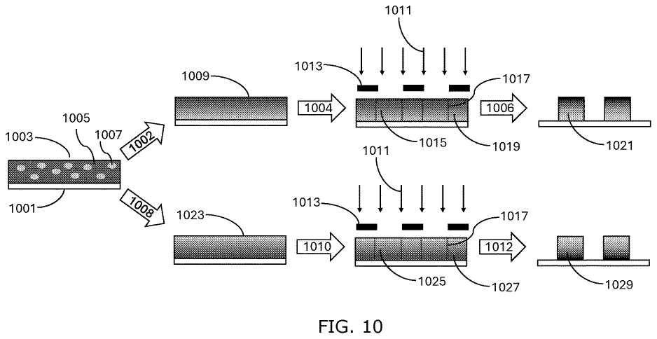

A more uniform radiation dose throughout the depth of the resist can generally alleviate, at least in part, positive or negative tapered resist profiles that may form during development, as depicted in FIG. 10. Substrate 1001 supports additive enhanced organotin photoresist film 1003 comprising organotin composition 1005 and absorption profile modifying additive composition 1007. In positive vertical gradient formation step 1002, the additive composition can migrate to the lower portion of the photoresist film to form positive vertically graduated organotin photoresist film 1009 wherein the concentration of the organotin composition increases from the bottom of the film to the top surface of the film. The gradient formation step 1002 can be thermally induced, for example during a PAB, or may occur spontaneously during deposition of one or more photoresist layers, depending on the materials and conditions selected. In exposure step 1004, radiation source 1011 is directed through photomask 1013, which may be a physical mask or a mechanism for directing radiation, to form exposed regions 1015 within projected image boundaries 1017 and unexposed regions 1019. In development step 1006, the unexposed regions are preferentially removed to form patterned features 1021 that generally correspond to the projected image boundaries. In some embodiments, the additive enhanced organotin photoresist film undergoes negative vertical gradient formation step 1008 alternatively instead of step 1002 wherein the additive composition preferentially migrates to the upper portion of the photoresist film to form negative vertically graduated organotin photoresist film 1023 wherein the concentration of the organotin composition decreases from the bottom of the film to the top surface of the film. The gradient formation step 1008 can be thermally induced, for example during a PAB, or may occur spontaneously during deposition depending on the materials and conditions selected. In exposure step 1010, radiation source 1011 is directed through photomask 1013 to form exposed regions 1025 within projected image boundaries 1017 and unexposed regions 1027. In development step 1012, the unexposed regions are preferentially removed to form patterned features 1029 that generally correspond to the projected image boundaries.

As noted above, water activity modulating additives generally have a boiling point greater than the solvent, such that the additive does not volatilize before the solvent and when much of the hydrolysis is likely to occur. Thus, the solvent selection may influence the additive selection. Water activity modulating additives that serve dual functionality as absorption profile modifying additives can generally have a low volatility, such that they are not fully evacuated from the film during a post application bake (PAB). The temperature and duration of the PAB can be carefully selected to ensure the additive does not fully volatilize and evacuate from the film, which are described further below. In some embodiments, water activity modulating additives that serve dual functionality as absorption profile modifiers have a boiling point or decomposition temperature between about 120° C. and about 600° C., while in other embodiments the boiling point or decomposition temperature of the additives is between about 140° C. and about 500° C., and between about 150° C. and 450° C. in further embodiments. A person of ordinary skill in the art will realize that additional temperature ranges and values within the explicit ranges above are contemplated and are within the scope of the present disclosure.

When the water activity modulating additive remains in the film at the time of irradiation and functions as an absorption profile modifier, the formation of a composition gradient may occur during deposition in some embodiments. In other embodiments, additive is distributed homogeneously throughout the film upon deposition and may form a composition gradient with the organotin composition during a post application bake (PAB). In further embodiments, the gradient may partially form during deposition and further develop during a post application bake. The temperature of the PAB can affect the intensity of the gradient formed, although in some embodiments increasing the PAB temperature increases the intensity of the composition gradient while it decreases the intensity of the composition gradient in other embodiments. As noted above, a plurality of deposition steps can be used to construct a more desirable effective concentration gradient.

In some embodiments, water activity modulating additives are represented by the chemical formula: X—R^{Q}-Q. Five genera of water activity modulating additives are based on this general formula. In a first genus 1) of Q, Q is a hydrocarbyl moiety with optional silicon atom substitutions and optional one or more sulfur atom substitutions, which in some embodiments has a low polarity and has from 9 to 31 total carbon, silicon and sulfur atoms and X is H or a polar functional group comprising a heteroatom. R^{Q} is an alkyl group or silyl group with 1 to 9 carbon atoms or a silicon atom, and generally no unsaturated groups or heteroatoms. While in other contexts, hydrocarbyl moieties can comprise heteroatoms, in the context of additives, hydrocarbyl groups are generally free of heteroatoms unless specifically indicated otherwise, and some specific embodiments with heteroatoms are specified below. In some contexts, silicon can exhibit chemistry reminiscent of carbon, which is adjacent in the periodic table, with less of its metalloid characteristics. Organosilicons can be similarly hydrophobic and can exhibit other desirable properties. However, in some embodiments hydrocarbyl moieties can optionally comprise unsaturated bonds, aromatic groups and combinations thereof, and specifically Q can comprise unsaturated bonds and aromatic groups. In some embodiments, the hydrocarbyl moiety Q has a low polarity and is characterized by a log(P) value greater or equal to about 3.0, or within the ranges presented above more generally for additives. While not wanting to be limited by theory, it is believed that the hydrophobicity of this moiety is responsible for its effectiveness as a water activity modulating additive.

In some embodiments Q is a cyclic, branched or unbranched alkene or alkane having from 9 to 31 carbons atoms represented by the formulas:

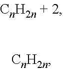

wherein 9≤n≤31, in which the upper formula is for open-chain molecules and the lower formula for cyclic molecules. In some embodiments, Q is an aromatic or aliphatic hydrocarbyl group having from 9 to 31 carbon atoms, which can be monocyclic or polycyclic. Desirable properties can be obtained with the substitution of silyl groups (such as —Si(CH₃)₃) on the hydrocarbyl structure. Polycyclic hydrocarbons have been identified as particularly useful hydrocarbyl moieties for water activity modulating additives, owing to their composition and balanced arrangement of low polarity C—H and C—C bonds. Sulfur atoms can be introduced into five-member low polarity aromatic moieties or hydrophobic sulfide groups, and Q can correspondingly comprise one or more sulfur atoms. Similarly, trimethylsilyl groups can be effective to introduce desirable hydrocarbon derivative compounds with good hydrophobic properties. Non-limiting suitable examples of hydrocarbyl moieties, with optional silyl groups, Q include nonane, 1-nonene, 2-nonene, 3-nonene, 4-nonene, decane, 1-decene, 2-decene, 3-decene, 4-decene, 5-decene, undecane, dodecane, tridecane, tetradecane, pentadecane, hexadecane, heptadecane, octadecane, nonadecane, eicosane, squalane, squalene, decalin, 1,3,5-trimethylbenzene (mesitylene), 1,2,4-trimethylbenzene, 1,2,3-trimethylbenze, cumene, o-cymene, p-cymene, m-cymene, durene, isodurene, prehnitene, n-propyl benzene, tert-butylbenzene, hexamethylbenzene, 2-phenylhexane, 1,3,5-triethylbenzene, bicyclo[4.4.0]decane, naphthalene, anthracene, tetracene, phenanthrene, chrysene, pyrene, triphenylene, perylene, phenalene, azulene, fluorene, helicene, butalene, tetracene, adamantane, iceane, diamantine, styrene, 4-vinyltoluene, 1,6-di(trimethylsilyl)hexane, 1,4-bis(trimethylsilyl)benzene, and the like.

In some embodiments where Q is a polycyclic aromatic hydrocarbon, the additive compound can have a relatively high melting point and can be a solid at room temperature. This is in contrast to useful organic solvents that comprise organotin precursor solutions which are generally liquids at room temperature. In other embodiments, the additive compound can be a liquid at room temperature. Notwithstanding its liquid form, the additive compounds are not regarded as a solvent in the context of the definition provided herein. The additives are generally present at a relatively low concentration relative to the solvent and the additives do not serve as the primary liquid medium for the dissolution of the organotin compositions.

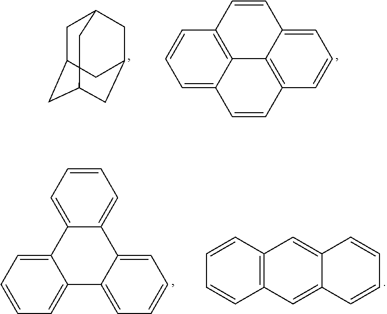

The substitution of one or more carbon atoms in the moiety Q for Si or S or a combination thereof can produce moieties with desirable values of log(P). Organosilo compounds (comprising C and Si), organothio compounds (comprising C and S), and organic compounds comprising both Si and S heteroatoms have been identified as particularly useful due to their composition of low polarity Si—C, S—C, C—C, and C—H bonds. In some embodiments, the moiety Q is an organic group having from 9 to 31 total carbon, sulfur, and silicon atoms and optionally comprising aromatic, silyl, and/or thiophene, functional groups, for example trimethylsilyl hexane, 1,6-di(trimethylsilyl)hexane, 1,5-di(trimethylsilyl)pentane, 1,4-di(trimethylsilyl)butane, bis(trimethylsilyl)methane, 1,3,5-tris(trimethylsilyl)benzene, 1,2,4-tris(trimethylsilyl)benzene, triethylsilyl hexane, triethylsilyl butane, tripropylsilyl butane, tripropyl silyl hexane, decyl methyl sulfide, nonyl phenyl sulfide, thiophene, thieno[3,2-b]thiopehene, thieno[2.3-b]thiophene, dithioeno[3,2-b: 2′,3′-d]thiophene, 3-Hexylthiophene, 2-Butylthiopehene, 3-(phenylsulfanyl)thiophene, 3-(Methylthio)thiophene, 2-(methylthio)thiophene, 2-5-bis(methylthio)thiopehene, 2,5-Bis(phenylthiol)thiophene, 2-(2-Ethylhexyl)thiophene, 3,4-diethyl-2,5-diphenyl thiophene, 3,5-diisopropyl-2,5-diphenyl thiophene, 1,4-bis(trimethylsilyl)benzene, 4,4-Dioctyl-4H-silolo[3,2-b: 4,5-b′]dithiophene, or Dimethyldiphenylsilane. In some embodiments, the overall additive structure X—R^{Q}-Q can comprise a S heteroatom as a thiol group (—SH), where X is generally the thiol group, which is further described below. In some embodiments, the overall structure X—R^{Q}-Q can be, for example, 1-decanethiol, tetradecanethiol, 2-phenylethanethiol, cyclohexanethiol, benzyl mercaptan, cyclopentanethiol, 2-propanethiol. In some embodiments, the additive structure X—R^{Q}-Q can be represented by the structures:

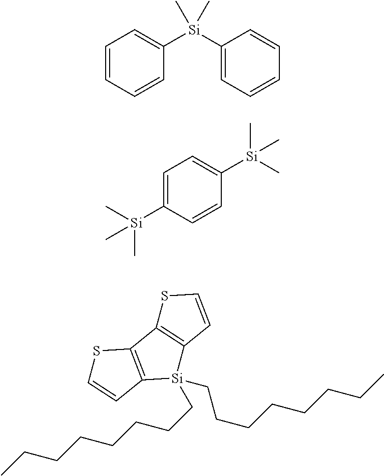

In some embodiments, X is hydrogen and allows the additive compound to substantially retain the relatively high log(P) of the hydrocarbyl moiety Q. This can be beneficial to increase the log(P) value of the additive. In other embodiments, X is a polar functional group which can allow for a controlled layer of additive to form on the top of the film, opposite the substrate. While not wanting to be limited by theory, it is believed that when X is a polar functional group, X serves as a polar tail capable of interfacing with tin-oxo and tin-hydroxo bonds. The resulting complex is amphiphilic such that the polar tail interfacing the tin-oxo bonds face the substrate while the hydrocarbyl moiety Q faces and interacts with the atmosphere. In some embodiments X can comprise a heteroatom and form a corresponding functional group, such as a hydroxyl group, a thiol group, an amine group, or a halogen such as Br, Cl, F, or I. An amphiphilic additive can alternatively be introduced to the precursor solutions as hydrochloride or other suitable acid based salts and represented by the formula X—R^{Q}-Q. HCl. The acid-additive adducts are convenient for introducing certain additives as stable forms, and the acid component is not contemplated to provide improved patterning properties to the photoresist formulations.

Other illustrative, nonlimiting examples of useful X—R^{Q}-Q additive structures for genus 1) are represented by the structures:

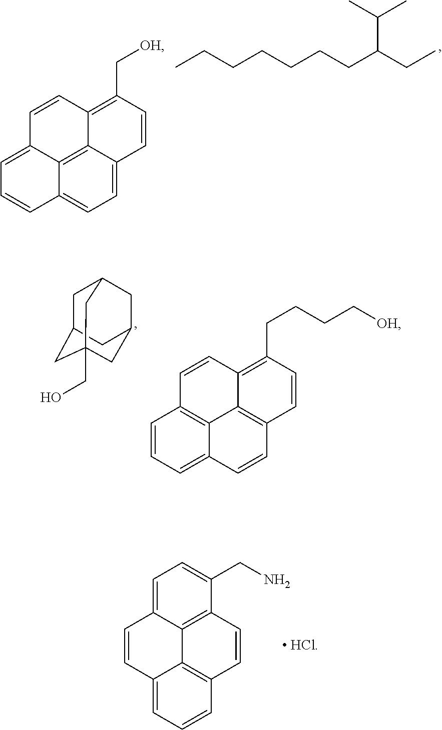

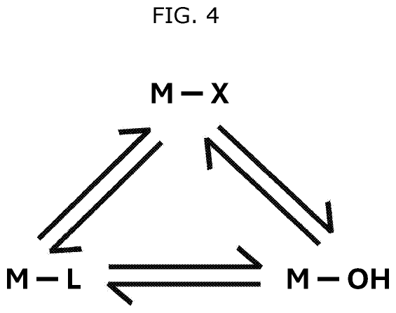

In some embodiments, the additive can modulate water activity by competing for coordination sites on the tin atoms that can otherwise coordinate with water molecules to participate in hydrolysis and/or condensation reactions. Additives in these embodiments may or may not have the hydrophobic properties, log(P) values, or boiling points of aforementioned embodiments. Some of these fall within genera 2)-5) of Q presented in the following. Effective compounds can bind, chelate, coordinate, or otherwise interact with tin atoms of the organotin clusters more readily than water molecules. While not wanting to be limited by theory, it is believed that an equilibrium exists between the amount of M-OH, M-L, and M-X bonds or interactions in the tin oxo hydroxo network in the precursor solution and in coatings deposited therefrom, wherein L is a hydrolysable ligand and X is a water activity modulating additive. The effect of the water modulating additive may additionally or alternatively involve ligating at a fifth or sixth coordination site around the tin atom, and blocking these sites may alter rates of hydrolysis. A simplified depiction of this equilibrium is shown in FIG. 4, although in practice the equilibrium may be more complex and even involve additional species, mechanisms, or considerations. To the extent that metal-additive bonds can form and dominate the equilibrium, the progression of hydrolysis (formation of M-OH bonds) and resulting condensation can be slowed or inhibited. These additives are generally added to organotin precursor solutions prior to deposition to provide functionality during spin coating, although the additive can be deposited simultaneously to an organotin precursor solution to realize a similar functionality.

In some embodiments, the additive compound can be a primary amine, a secondary amine, a tertiary amine, a diamine, an alkenol, an alkynol, or a combination thereof. The amines are non-hindered. In a more detailed discussion to follow, these genera are organized in individual genus 2)-5). While not wanting to be limited by theory it is believed that the amine (—NH) and alcohol (—OH) functional groups can bind, chelate, coordinate or otherwise interact with tin atoms to occupy active sites to retard hydrolysis and/or condensation mechanisms which can inhibit the formation of large tin oligomers or crystalline domains. As used herein, the term amines can more broadly refer to primary amines, secondary amines, and tertiary amines unless specifically indicated otherwise. Hindered amines can provide alternative functionality relating to radical quenching, as described in published U.S. patent application 2025/0251662 to Eberle et al. (hereinafter the '662 application), entitled “Radical Scavenger Additives for Metal Oxide based Resists and Precursor Solutions,” incorporated herein by reference

The amine additives within genus 2) can generally be represented by the formula NR¹R²R³ and by the structure:

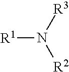

wherein R¹, R², and R³ are independently H or a linear, branched, or cyclic alkyl groups having from 1 to 6 carbon atoms, for example methyl, ethyl, n-propyl, isopropyl, n-butyl, isobutyl, sec-butyl, tert-butyl, n-pentyl, n-hexyl, tert-amyl, cyclopropyl, cyclobutyl, cyclopentyl, or cyclohexyl. This formula can be considered in the notation above, where X═H, HR^{Q} is R¹, and Q is NR²R³, so that in these embodiments, Q has a heteroatom. In some embodiments R¹, R², or R³ can independently be a benzyl group or more generally —R⁴A, where R⁴ is an alkyl group with 1 to 8 carbon atoms and A is a phenyl or other aromatic group. In some embodiments, the amine is a primary amine wherein R² and R³ are hydrogen, a secondary amine wherein one of R² or R³ is hydrogen, or a tertiary amine wherein none of R¹, R², or R³ are hydrogen. R¹, R² and R³ do not connect with each other to form cyclic moieties. Non limiting examples of suitable amine additive compounds include, n-propylamine, isopropylamine, n-butylamine, sec-butylamine, tert-butylamine, phenylamine, diethylamine, dipropylamine, diisopropylamine, N-tert-butylmethylamine, dipenylamine, triethylamine, N,N-dimethylethylamine, N,N-diethylmethylamine, N,N-dimethylisopropylamine, N-isopropyl-N-methyl-tert-butylamine, and combinations thereof, all of which are commercially available from chemical suppliers such as Millipore Sigma (Burlington, MA), Thermo Fisher Scientific (Waltham, MA), and BASF (Ludwigshafen, DE). Generally, amines with higher volatilities relative to the precursor solution solvent, such as those which are a gas at room temperature, may be less desirable as they are not substantially retained in the coating during spin coating to provide a meaningful effect. As the solvent evaporates during spin coating, it can be desirable for the amine additives to be preferentially retained in the coating to some extent to coordinate with Sn. Accordingly, in some embodiments the amine additive can have a lower boiling point than the precursor solution solvent or solvent blend. In some embodiments, the amine additives can have a boiling point higher than about 75° C., higher than about 85° C. in other embodiments, and in further embodiments higher than about 100° C.

Hindered amines can be effective as radical scavengers. The use of radical scavengers including hindered amines has been described in the '662 application, cited above. The amines described herein are not hindered in the sense that lower steric extent can facilitate the efficacy of the amines to inhibit or slow hydrolysis relating to the tin ligands. Thus, the non-hindered amines can provide alternative functionality that meet the objectives described herein with respect to slowing hydrolysis through interactions with the tin. Also, non-hindered amines generally may have a reduced hydrophilic nature so that the unhindered amines can be more effective at reducing water penetration into the material.

In some embodiments, the additive can be an alkenol represented by the formula:

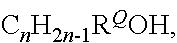

where 2≤n≤11 and R^{Q} has 1-8 carbon atoms for these embodiments. This genus corresponds with genus 3) relative to the general notation above. As used herein, alkenol is specified somewhat differently than the traditional enol that can undergo enol-keto tautomerism since at least one extra carbon separates the alkenyl group and the hydroxyl group. The alkenol can be linear or branched and comprises an unsaturated C—C bond. Non-limiting examples of suitable alkenol additives include 2-propen-1-ol, 2-buten-1-ol, 3-buten-1-ol, 2-penten-1-ol, 3-penten-1-ol, 4-penten-1-ol, 2-hexen-1-ol, 3-hexen-1-ol, 4-hexen-1-ol, 5-hexen-1-ol, 2-hepten-1-ol, 3-hepten-1-ol, 4-hepten-1-ol, 5-hepten-1-ol, 6-hepten-1-ol, 2-octen-1-ol, 3-octen-1-ol, 4-octen-1-ol, 5-octen-1-ol, 6-octen-1-ol, 7-octen-1-ol, 2-nonen-1-ol, 3-nonen-1-ol, 4-nonen-1-ol, 5-nonen-1-ol, 6-nonen-1-ol, 7-nonen-1-ol, 8-nonen-1-ol, 2-decen-1-ol, 3-decene-1-ol, 4-decen-1-ol, 5-decen-1-ol, 6-decen-1-ol, 7-decen-1-ol, 8-decen-1-ol, 9-decen-1-ol, 2-undecen-1-ol, 6-undecen-1-ol, 10-undecen-1-ol, 2-methylprop-2-en-1-ol, 3-methyl-2-buten-1-ol, 3-methyl-3-buten-1-ol, 2-methyl-3-buten-2-ol, 2-methyl-3-buten-1-ol, 2-methyl-2-buten-1-ol, 3,3-dimethyl-2-buten-1-ol, 3-methyl-2-penten-1-ol, 3-methyl-3-penten-1-ol, 4-methyl-3-hexen-1-ol, 3-methyl-4-hexen-1-ol, 2-methyl-4-hexen-1-ol, 3-methyl-2-hexen-1-ol, and combinations thereof, all of which are commercially available from chemical suppliers such as Millipore Sigma (Burlington, MA), Thermo Fisher Scientific (Waltham, MA), and TCI Chemical (Tokyo, JP). The hydrophobic components can resist water migration, while the OH group may ligate to tin to inhibit hydrolysis.

In some embodiments, the additive can be an alkynol represented by the formula:

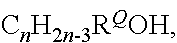

where 2≤n≤11 and R^{Q} has 1-8 carbon atoms for these embodiments. In terms of the notation above, X is OH and Q is CₙH₂ₙ₋₃, and this genus corresponds with genus 4) relative to the general formula above. As used herein, alkynol is specified to have at least one carbon spacing the alkyne group and the hydroxyl group, which removes the possibility of a tautomerization to a corresponding ketene. The alkynol can be linear or branched and comprises an unsaturated C≡C bond. Non-limiting examples of suitable alkynol additives include propargyl alcohol, 2-butyn-1-ol, 3-butyn-1-ol, 2-methyl-3-butyn-2-ol, 3-methyl-1-butyn-3-ol, 2-pentyn-1-ol, 4-pentyn-1-ol, 5-hexyn-1-ol, 4-hexyn-2-ol, 3-hexyn-1-ol, 2-heptyn-1-ol, 4-heptyn-1-ol, 5-heptyn-1-ol, 6-octyn-1-ol, 5-octyn-1-ol, 4-octyn-1-ol, 3-octyn-1-ol, 2-octyn-1-ol, 3-nonyn-1-ol, 5-nonyn-1-ol, 6-nonyn-1-ol, 2-decyne-1-ol, 3-decyne-1-ol, 5-decyne-1-ol, 2-undecyne-1-ol, 3-undecyne-1-ol, and combinations thereof, (all of which are commercially available from chemical suppliers such as Millipore Sigma (Burlington, MA), Thermo Fisher Scientific (Waltham, MA), and TCI Chemicals (Tokyo, JP). These compounds can have higher boiling points relative to the precursor solution solvent or solvent blends and can be expected to inhibit hydrolysis of ligands to tin.

Applicant has previously described solvent blends of alcohols that can effectively coordinate with tin, in published US Patent Application 2023/0143592 (hereinafter referred to as the '592 application) to Jiang, et al. entitled “Stability-enhanced organotin photoresist compositions”, which is hereby incorporated by reference. While not wanting to be limited by theory, the unsaturated alcohols described herein are believed to coordinate more effectively to tin atoms than the conventional saturated alcohols described in the '592 application, owing to the presence of unsaturated carbon-carbon bonds. The unsaturated bonds can stabilize the conjugate base of the alcohol which can be quantified by the alcohol's pKa. Alcohols with a lower pKa value generally form more stable conjugate bases which may behave as stronger Lewis bases toward tin atoms. In the context of the three way equilibrium between water, hydrolysable ligands, and water activity modulating additive ligands, alcohols with lower pKa values can more effectively compete for coordination sites on tin atoms. By shifting this equilibrium and occupying coordination sites on the tin atoms, the additive ligands can suppress and slow hydrolysis mechanisms to reduce premature hydrolysis and/or condensation during storage and moderate controlled hydrolysis mechanisms during spin coating which can promote formation of more desirable and amorphous tin oxo-hydroxo network.

In some embodiments, the additive compound can be a diamine comprising a 1 to 6 C hydrocarbyl linkage or aromatic substituted with two terminal groups independently selected from amine (NH₂), alkylamine (NHR⁴), and dialkylamine (NR⁴R⁵). The diamine additives can generally be represented by the formula R⁴R⁵N-A-NR⁶R⁷ where R⁴, R⁵, R⁶, and R⁷ are independently H, phenyl, or linear, branched, or cyclic alkyl groups having from 1 to 6 carbon atoms and A is a hydrocarbyl linkage or aromatic group having from 1 to 6 carbon atoms. This formula can be rewritten in the general notation from above where X is-NR⁶R⁷, R^{Q} is A and Q is R⁴R⁵N—. In this embodiment Q has a heteroatom. This genus of compounds corresponds to genus 5) in the context of the general formula given above. Non-limiting examples of suitable diamine additives include ethylene diamine, methane diamine, p-phenylene diamine, o-phenylene diamine, m-phenylene diamine, propylene diamine, butylene diamine, pentamethylene diamine, and hexamethylene diamine, tetramethyldiaminomethane, and tetraethylmethanediamine.

The water activity modulating additive enhanced organotin photoresist precursor solutions, also more simply referred to as additive enhanced precursor solutions, can generally comprise a solvent, an organotin precursor composition, and a water activity modulating additive. The additive enhanced precursor solutions can be prepared through a variety of methods, although the sequence of the method is generally believed to be not significant to the utility of the precursor solution as long as the final product comprises a solvent, an organotin composition, and an additive. In some embodiments, an organotin precursor composition can be combined with the solvent and an additive can be added thereafter. In some embodiments, it can be desirable to combine the additive shortly after the precursor composition has been added to the solvent which can contain water, as to prevent premature oligomerization which can be irreversible and compromise the effects of the additives. As noted below, the initial water amounts in the precursor solution can be set to provide consistent performance, which can also reduce the influence of the hydrolysis in the precursor solutions that are generally stored in a container sealed from access to atmospheric water. In other embodiments, the additive can be combined in a mixture with the organotin composition and the mixture can be added to a solvent. In further embodiments, the additive can be added to the solvent to form an additive enhanced solvent system to which the organotin composition can be added.

In some embodiments, the organotin composition comprises one distinct organotin compound that is introduced into the solvent. In some embodiments, the organotin composition comprises a mixture of two or more organotin compounds represented by the formulas RSnL₃ and R′SnL′₃ having different hydrocarbyl R and R′ groups with the same and/or different L and L′ groups bound accordingly. In some embodiments, the organotin photoresist composition has R ligands comprising a blend of a linear alkyl ligand and a non-linear alkyl ligand. In some embodiments, a blend of a linear alkyl ligand and a non-linear alkyl ligand comprises a branched alkyl group, a cyclo-alkyl group, an unsaturated group, such as a dialkylene group, or an aryl group. In some embodiments, the organotin composition is a mixture of distinct organotin compounds having methyl ligands and tert-butyl ligands, respectively. In some embodiments, the precursor compositions comprise a blend of organotin compounds having the same and/or different L groups.

In some embodiments, the organotin composition comprises one or more organotin compounds independently with hydrolysable L ligands comprising a dialkylamide, an alkylsilylamide, an alkyloxide, an alkylacetylide, or a combination thereof. In other embodiments, the organotin composition comprises one or more organotin compounds with L ligands independently comprising methoxide, ethoxide, propoxide, iso-propoxide, butoxide, iso-butoxide, tert-butoxide, tert-amyloxide, pentoxide, iso-pentoxide, dimethyl amide, diethyl amide, diisopropyl amide, trimethylsilyl amide, other isomers thereof, or combinations thereof. Depending on the solvent and additive as well as the hydrolysable ligands of a plurality of organotin compounds, dissolved organotin compounds can possibly exchange ligands to some degree in the solution, with ligands of other organotin compounds and/or solvent or water molecules and/or additives, over a period of storage. In some embodiments, the precursor compounds can hydrolyze partially or completely in solution, and the precursor solution can further comprise the hydrolysis products of the organotin precursor compounds. References to precursors solution compositions generally reference the compounds added to form the solution without reference to potential evolution of the compositions during storage unless explicitly indicated otherwise. In any case, though, while transient clusters may or may not form, the stabilized solutions should not form significant precipitates upon storage and generally undergo little stable cluster formation such that a desirable uniform coating can be formed.

In embodiments wherein a blend of different organotin compounds are used, any one of the distinct organotin compounds can comprise from about 1 mol. % to about 99 mol. % of the total organotin moles in some embodiments, from about 5 mol. % to about 95 mol. % of the total organotin moles in other embodiments, from about 10 mol. % to about 90 mol. % of the total organotin moles in other embodiments, and from about 15 mol. % to about 85 mol. % of the total organotin moles in further embodiments. In the Examples below, organotin precursor solutions comprising a mixture of two distinct alkyltin tri-tert-amyl alkoxide compounds are demonstrated. As is conventional in this art, the hydrocarbyl group can be referred to as an alkyl group even though the group can have unsaturated bonds, aryl groups, heteroatoms, and so forth. A person of ordinary skill in the art will recognize that additional ranges of molar concentrations of organotin compounds within the explicit ranges above are contemplated and are within the present disclosure.

For the additives, there are at least two time points in which concentrations are of note, in the precursor solution prior to deposition and in the organotin film prior to the post application bake. Depending on the volatility of the additive, the ratio of additive to tin atoms may or may not be substantially different at these two time points. While the additive should be less volatile than the solvent, which may be substantially removed prior to a post application bake (PAB) or other pre-irradiation processing, it may be fine for the present purposes for a significant fraction of the additive to evaporate with a substantial amount of additive remaining at the start of a PAB. The resist precursor composition can be conveniently specified based on tin ion molar concentration. In general, the resist precursor solution generally comprises from about 0.0025 M to about 1 M tin cation, in some embodiments from about 0.004 M to about 0.9 M, in further embodiments from about 0.005 M to about 0.75 M, in some embodiments from about 0.01 M to about 1 M, and in additional embodiments from about 0.01 M to about 0.5 M tin cation. In some embodiments, prior to the PAB initiation, the organotin patterning film can have an additive to Sn ratio from about 0.1 to about 0.5, from about 0.05 to about 0.15 in other embodiments, and from about 0.2 to about 1.0 in further embodiments. In the precursor solution, the additive-enhanced organotin composition can have an additive to tin ratio from a lower range value in respective embodiments of about 0.01, about 0.0.05, about 0.1, 0.25 or 0.5 each to any upper range value in respective embodiment of about 10, about 5, about 2.5, about 1.0 or about 0.5, such as about 0.01 to about 0.5 or about 0.1 to about 10 or about 0.5 to about 1. As noted above, for non-volatile additives, the ratio of additive to tin cation in the precursor solution and in film generally are approximately the same. A person of ordinary skill in the art will recognize that additional ranges of additive amounts in organotin photoresist precursor solutions within the explicit ranges above are contemplated and are within the present disclosure.

In conjunction with using a selected amount of additive as a water activity modulating compound, it can be desirable to control the amount of water provided in the additive-enhanced organotin photoresist precursor composition to a specific level. Water can react with the organotin species to form hydrolysis/condensation products, although the limited amounts of water correspondingly limit the hydrolysis products. Organotin photoresist solutions comprising different amounts of water can result in different degrees of hydrolysis/condensation occurring and thus different distributions of hydrolysis/condensation products within the different solutions which may impact resist performance. Therefore, to improve batch to batch reproducibility of organotin photoresist precursor solutions it is desirable to controllably target specific concentrations of water formulated into the photoresist precursor solutions. Desirable amounts of water can generally be expressed as either absolute concentrations, such as molarity (mol/L) or parts-per-million (ppm) by weight, or the desirable amounts of water can be expressed as molar ratios with respect to the Sn concentration. In some embodiments, the additive-enhanced organotin photoresist precursor solutions can comprise a selected concentration of water from about 200 ppm to about 10,000 ppm water by weight, from about 250 ppm to about 8,000 ppm in further embodiments, and from about 300 ppm to about 5,000 ppm in other embodiments. In some embodiments, the additive-enhanced organotin photoresist solutions can comprise a selected molar ratio of water to Sn from about 0.025 to about 20, from about 0.05 to about 15 in some embodiments, and from about 0.1 to about 10. A person of ordinary skill in the art will recognize that additional ranges of water in organotin photoresist precursor solutions within the explicit ranges above are contemplated and are within the present disclosure.

The additive-enhanced organotin precursor solutions can generally comprise any useful organic solvent or solvent blend known in the semiconductor manufacturing arts that dissolve the relevant compositions. As used herein, a solvent refers to a volatile liquid component of the precursor solution present in an amount sufficient to dissolve or disperse the organotin composition and any additive compounds. In some embodiments, the solvent constitutes at least 40% and up to 99.9% by weight of the total weight of the photoresist precursor solution, at least 50% and up to 99% by weight in other embodiments, and in further embodiments at least 60% and up to 98% by weight of the total weight of the photoresist precursor solution. Unless otherwise stated, the term solvent does not encompass additive compounds that are present at lower concentrations and do not function as a primary component of the liquid medium for the dissolution of the organotin composition. While a solvent can comprise multiple liquid components that are miscible or otherwise form a uniform single phase blend, each solvent component generally comprises at least about 10 volume percent of the solvent. Since suitable solvents are generally organic, the distinction between a solvent and an additive may be blurred, although if a compound is within the formula specified above (Q-R^{Q}—X) or any of the specific genera under the formula, then the compound can be considered an additive and not a solvent. Also, a solvent blend can comprise appropriate hydrophobic compounds in reasonable amounts to form a homogenous solution. Additives can be identified by persistence in a substantial amount post spin coating, corresponding to the desired additive concentration, following pre-irradiation processing. Persistence of additives after spin coating can be based on a higher boiling point relative to the solvent as well as an affinity for tin that can resist rapid evaporation. A fraction of the additive compound can be removed during the pre-irradiation processing, so an initial amount of additive can be selected accordingly. In some embodiments, as noted above, a separate deposit of an additive solution can also be deposited, which may or may not comprise organotin. A separate deposit of additive can supplement the total amount of additive, provide additive that may not be desirably maintained during processing of the bulk organotin coating, and/or alter the distribution of additive concentration through the thickness of the patternable coating. Suitable solvents are generally liquid at room temperature and can include alcohols, ethers, esters, ketones, alkanes, aromatics, and combinations and mixtures thereof. Solvent mixtures along with additives in selected amounts should have appropriate solubilities to form a homogenous solution without phase separation. Suitable organic solvents include, for example, alcohols having 1 to 8 carbons or blends thereof. Generally, the solvents are at least 50 weight percent alcohols with any remaining organic solvent liquids being soluble in the alcohol, such as an alkane having 1 to 8 carbons (such as pentane or hexane), an aromatic hydrocarbon having 1 to 8 carbons (such as toluene or benzene), ether (such as diethyl ether, C₂H₅OC₂H₅), or mixtures thereof. In some embodiments, the solvent is at least 90 weight percent alcohol, and the solvent can be effectively alcohol with just trace impurities of other compounds. In some embodiments, the solvent can be a blend of two or more alcohols. Suitable alcohols are generally alcohols with a melting point of no more than about 10° C., such as methanol, ethanol, propanol, butanol, pentanol, hexanol, heptanol, octanol, isomers thereof, and mixtures thereof. Selection of a solvent or solvent blend can be influenced by solubility of the selected additive(s) at the selected concentration.

In some embodiments, the additive enhanced organotin precursor solutions can further comprise a radical scavenging additive. The addition of a radical scavenging compound can reduce undesirable effects of radical contaminants which can increase wafer to wafer consistency amidst changes to the processing environment. To decrease deleterious effects from radicals, further additives can be included in the precursor solutions to scavenge radicals. Such additives have been shown to be beneficial, as described in the '662 application cited above. A suitable concentration of radical scavenger can depend significantly on the agent used, but generally the concentration of radical scavenger in the precursor solution can be from about 0.000025M to about 0.4M, and any subrange within this concentration range is contemplated and recognized to be in this disclosure.

Radical scavenger compounds can include, for example, H-donor radical scavengers, such as phenolic compounds and hindered amines. The phenolic compounds can be characterized by the presence of a substituted aromatic ring which can improve their ability to form relatively stable radicals after hydrogen atom transfer. In some embodiments, the H-donor radical scavenger is a hindered phenol compound having an aromatic ring substituted with an electron-donating group. In some embodiments, the H-donor radical scavenger is butylated hydroxytoluene (BHT) or butylated hydroxyanisole (BHA), and more general embodiments are described in the '662 application. In some embodiments, the H-donor radical scavenger is an aromatic diol. In some embodiments, the H-donor radical scavenger is an alkoxyphenol, hindered aromatic amine, or derivative thereof.

In some embodiments, the radical scavenging additive is a hindered amine compound. The hindered amine compound can react with oxygen or reactive oxygen species to form a stable and sterically hindered aminoxyl (—NO·) radical which can preferentially react with other radical species instead of the non-radical components of the photoresist. In some embodiments, the radical scavenger additive is TEMPO ((2,2,6,6-tetramethylpiperidin-1-yl)oxyl) or TEMPOL ((4-Hydroxy-2,2,6,6-Tetramethylpiperidin-1-yl)oxyl). In some embodiments, the radical scavenger additive is 2-phenyl-4,4,5,5-tetramethylimidazoline-1-oxyl 3-oxide (PTIO).

The additive-enhanced organotin photoresist precursor solutions can be used to form radiation-patternable additive-enhanced organotin oxide hydroxide materials, and such coatings can be formed using any suitable method known in the art. Spin coating can be particularly desirable for forming coatings using the additive-enhanced organotin photoresist compositions. In a typical spin coating process, a volume of a photoresist solution is introduced onto the surface of a substrate, and the substrate is rotated at high speeds to drive rapid evaporation and hydrolysis processes to enable the formation of a radiation patternable coating. In some embodiments, the substrate can be spun at rates (i.e., spin speeds) from about 500 rpm to about 10,000 rpm, in further embodiments from about 1000 rpm to about 7500 rpm, and in additional embodiments from about 2000 rpm to about 6000 rpm. The spin speed can be adjusted to obtain a desired coating thickness. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. A person or ordinary skill in the art will recognize that additional ranges of spin coating parameters within the explicit ranges above are contemplated and are within the present disclosure.

As noted above, additive or additives can be deposited in one or more deposition steps, for example, to obtain a more desirable distribution of additive through the thickness of the coating. In some embodiments, the bulk of the coating can be deposited in a single coating step with one or more supplemental coatings below and/or above the bulk coating, wherein such a supplemental coating may have a dry thickness less than about 50% of the bulk coating thickness. For example, a thin undercoating and/or a thin overcoating can be deposited to provide a greater additive concentration along the bottom of the coating or top of the coating to reduce T-topping and/or footer effects. The degree of interpenetration of adjacent coating layers may depend on the processing between layer depositions. For example, deposition of a subsequent layer on a gel layer that is not fully dry may result in greater interpenetration of adjacent layers, while subsequent deposition on a fully dried previous layer may result in little or no interpenetration of adjacent layers. Thus, if a post application bake is used, separate bake steps can be applied after each layer deposition or a single post application bake can be applied following deposition of one or more layers, or some combinations thereof can be used. The process conditions for a post application bake are described below and can be equally applicable in this context and can be considered as if written explicitly here.

A substrate generally presents a surface onto which the coating material can be deposited, and the substrate may comprise a plurality of layers in which the surface relates to an upper-most layer. The substrate surface can be treated to prepare the surface for adhesion of the coating material. Prior to preparation of the surface, the surface can be cleaned and/or smoothed as appropriate. Suitable substrate surfaces can comprise any reasonable material. For semiconductor applications, a suitable substrate generally comprises a semiconductor wafer. Some substrates of interest include, for example, silicon wafers, silica substrates, other inorganic materials, polymer substrates, such as organic polymers, composites thereof and combinations thereof and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The thickness of the coating generally can be a function of the precursor solution concentration, viscosity, and the spin speed for spin coating. As noted above, supplemental coating layers can be applied to achieve an additive distribution more closely aligned with a desired distribution. The full coating parameters in this paragraph include all of the layers deposited if there are multiple layers. Parameters for supplemental coating layers themselves are described further above. For other coating processes, the thickness can generally also be adjusted through the selection of the coating parameters. In some embodiments, it can be desirable to use a thin coating to facilitate formation of small and highly resolved features in the subsequent patterning process. For example, the coating materials after drying can have an average thickness of no more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods, such as x-ray reflectivity and/or ellipsometry, based on the optical properties of the film. In general, the coatings are relatively uniform to facilitate processing. In some embodiments, such as high uniformity coatings on reasonably sized substrates, the evaluation of coating uniformity or flatness may be evaluated with, for example, a 1-centimeter edge exclusion, i.e., the coating uniformity is not evaluated for portions of the coating within 1 centimeter of the edge, although other suitable edge exclusions can be selected.

While heating may not be needed for successful application of the deposition process, it can be desirable to heat the coated substrate to densify the coating material, to speed the processing, to increase the reproducibility of the process, and/or to facilitate vaporization of the hydrolysis by-products, such as alcohols and/or amines. Selection of the post application bake conditions can be influenced by the desire to remove, partially remove or not substantially remove an organic additive, which in turn can depend on the properties of the additive. In embodiments in which heating of the coated substrate is performed prior to irradiation, the coated substrate can be heated to temperatures from about 45° C. to about 250° C., and in further embodiments from about 55° C. to about 225° C. The heating can generally be performed for at least about 0.1 minute, in further embodiments for about 0.5 minutes to about 30 minutes, and in additional embodiments from about 0.75 minutes to about 10 minutes. A person of ordinary skill in the art will recognize that additional ranges of heating temperatures and times within the explicit ranges above are contemplated and are within the present disclosure. Alternative processing without a post application bake has been described, in which, alternative drying processes are used, such as extended spin coating or blowing, see copending U.S. provisional patent application 63/871,008 to De Schepper et al., entitled “Deposition and Processing Methods for Organometallic Photoresists,” incorporated herein by reference. Alternative processing to avoid a post application bake can be used in some embodiments.

While additives generally have a boiling point greater than the boiling point of the precursor solution solvent and interactions with the organotin may slow loss of the additive, it may or may not be desirable for the additive to remain during irradiation of the patternable coating. Generally, the coating at the time of irradiation should effectively be fully hydrolyzed into an oxo-hydroxo network, which can be a relatively uniform amorphous matrix. The additive can be effective during the hydrolysis process to slow or modulate the hydrolysis to encourage forming the amorphous uniform material with less ordered domains by way of breaking up clustering during the hydrolysis process. If the additive remains during the irradiation step, some additives may help to modulate absorption of radiation to achieve more uniform effects of the radiation through the thickness of the coating. In any case, the additive should not disrupt the development process.

Following exposure to radiation and the formation of a latent image, a subsequent post-exposure bake (PEB) is typically performed. A post-exposure bake (PEB) process can enhance the contrast of material properties between the exposed regions comprising depleted Sn—C bonds and increased metal oxide character and the unexposed regions comprising substantially intact Sn—C bonds. In some embodiments, the PEB can be performed at temperatures from about 45° C. to about 250° C., in additional embodiments from about 50° C. to about 190° C. and in further embodiments from about 90° C. to about 185° C. The post exposure heating can generally be performed for at least about 0.1 minute, in further embodiments from about 0.5 minutes to about 30 minutes and in additional embodiments from about 0.75 minutes to about 10 minutes. A PEB step can be performed in air, inert gas or a specific gas environment, such as enriched on CO₂. In some embodiment, processing between irradiation and development can also include rest steps and/or multiple PEB steps, each of which can be performed similarly under selected atmospheres. See published U.S. patent application 2021/0271170 to Telecky et al., entitled “Process Environment for Inorganic Resist Patterning”, which is hereby incorporated by reference. A person of ordinary skill in the art will recognize that additional ranges of PEB temperatures and times within the explicit ranges above are contemplated and are within the scope of the present disclosure.

Following performing a PEB, development of the image comprises contacting the exposed coating material having a latent image comprising exposed and unexposed regions to a developer composition to preferentially remove either the unexposed regions to form the negative image or the exposed regions to form the positive image. The exposed regions of organotin oxide hydroxide coatings are generally more hydrophilic in character than the unexposed regions and are thus more soluble in aqueous bases and less soluble in organic solvents; conversely, unexposed regions are generally more hydrophobic and are thus more soluble in organic solvents and less soluble in aqueous bases. If additive remains during irradiation and following PEB, the additive generally should not significantly alter the development process. The exemplified additives provide appropriate solubilities for consistency of the development process.

For positive tone imaging, suitable developers can generally be aqueous bases. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable positive tone developers. In general, the quaternary ammonium hydroxides of particular interest can be represented with the formula R₄NOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent. Furthermore, mixed quaternary tetraalkyl ammonium hydroxides can be used. In some embodiments, the developer can comprise from about 0.5 to about 30 weight percent tetraalkyl ammonium hydroxides, in further embodiments from about 1 to about 25 weight percent tetraalkyl ammonium hydroxides and in other embodiments from about 1.25 to about 20 weight percent tetraalkylammonium hydroxides. A person of ordinary skill in the art will recognize that additional ranges of developer concentrations within the explicit ranges above are contemplated and are within the present disclosure.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity, and potential chemical interactions with other process material. In particular, suitable developers include, for example, aromatic compounds (e.g., benzene, xylenes, toluene), esters (e.g., propylene glycol monomethyl ester acetate (PGMEA), ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. Improved developer compositions have been described in published U.S. Patent Application No.: 2020/0326627 to Jiang et al., entitled “Organometallic Photoresist Developer Compositions and Processing Methods,” incorporated herein by reference. Improved developer solutions generally comprise a reference organic solvent composition and an additive composition having a higher polarity and/or hydrogen-bonding character than the reference solvent composition. In one example, an improved developer composition can comprise PGMEA and acetic acid. The development can be performed for about 5 seconds to about 30 minutes, in further embodiments from about 8 seconds to about 15 minutes and in addition embodiments from about 10 seconds to about 10 minutes. A person of ordinary skill in the art will recognize that additional ranges within the explicit ranges above are contemplated and are within the present disclosure.

Additional useful developer compositions for organotin oxide photoresists have been described in U.S. Pat. No. 12,416,861 to Jiang et al., entitled “Organometallic Photoresist Developer Compositions and Processing Methods”, incorporated herein by reference. In particular, developers can have differing amounts of more polar or less polar components, which can be specified more specifically with solubility parameters. In some embodiments, the solvent blend can comprise at least two solvents with at least 55 volume % of one or more solvents each independently having a sum of Hansen solubility parameter δH+δP of no more than about 16 (J/cm³)^{1/2}, and with from about 0.25 volume % to about 45 volume % of one or more solvents each independently having a sum of Hansen solubility parameter δH+SP of at least about 16 (J/cm³)^{1/2}. A double bake-double develop processing can be performed in which the second development can involve a developed for a negative tone pattern comprising all or a larger percentage of a solvent having a sum of Hansen solubility parameter δH+δP of at least about 16 (J/cm³)^{1/2}, or a positive tone developer can be used in the second step of a negative tone patterning process.

It has also been discovered that solventless development, also referred to as dry development, can be employed with organotin materials for negative tone patterning wherein selective removal of the non-irradiated regions of the photoresist is achieved by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant (reactive gas) that facilitates removal of non-irradiated regions. In some embodiments, the developer can be HBr or HBr plasma. In other embodiments, the reactive developer gas can be a compound QₓZ_{y} or where Q is B, Al, Si, C, S, or SO with x>0 and Z is Cl, H, Br, or F with y>0. In further embodiments, the reactive developer gas can be an amine, a silyl halide, an alcohol, an amide, a sulfonic acid, a carboxylic acid, a thiol, tin halide, germanium halide, and mixtures thereof. The reactive gas species can be introduced in a gaseous form or activated into a plasma state to enhance reactivity. Following development, a rinse step can be conducted using water, a positive tone developer solution or the like, if desired to further remove undesired material from the pattern, and such methods have been described in U.S. Pat. No. 11,480,874 to Kocsis et al., entitled “Patterned Organometallic Photoresists and Methods of Patterning,” incorporated herein by reference.

Solventless development can be performed at various process conditions and the process conditions can be selected to achieve the desired development for certain developer species and organometallic coatings. The temperature of the developer gas or etch chamber can influence the efficacy of the solventless development, as can the duration of the development, and the pressure of the etch chamber during development. In some embodiments, the solventless development can be performed at a temperature from about 10° C. to about 100° C., from about 20° C. to about 80° C., or from about 30° C. to about 60° C. In other embodiments, the solventless development can be performed at a temperature from about 100° C. to about 250° C., from about 120° C. to about 230° C., or from about 150° C. to about 200° C. In some embodiments, the solventless development process can be performed for about 10 seconds, about 20 seconds, or about 40 seconds. In other embodiments, the solventless development process can be performed for more than about 3 seconds and less than about 5 minutes, from about 10 seconds to about 2 minutes in further embodiments, and from about 20 seconds to about 60 seconds in yet further embodiments. In some embodiments, the solventless development process can be performed at reduced pressures in other embodiments the solventless development process can be performed at near atmospheric pressures, and in other embodiments the solvent development process can be performed at higher than atmospheric pressures. In other embodiments pressure can be from about 0.1 mTorr (mT) to about 800 mT, in other embodiments the pressure can be from about 1 mT to about 500 mT, and from about 10 mT to about 300 mT in further embodiments. In embodiments wherein the solventless development process is conducted at pressures near or above atmospheric pressure, the solventless development process can be performed at pressures from about 100 Torr to about 1000 Torr, from about 100 Torr to about 800 Torr in further embodiments, and from about 200 Torr to about 800 Torr in other embodiments. A person of ordinary skill in the art will realize that additional values of temperatures, durations, and pressures within the explicitly recited ranges above are contemplated and part of the present disclosure.

After completion of the development step and any optional rinses, the patterned wafers can be treated to further condense the patterned material and to further dehydrate, densify, or remove residual developer and/or additive from the material. The treatment can involve heat, exposure to a suitable plasma, and/or exposure to radiation. If any additive remains at this stage of processing, such a post development treatment can be designed to facilitate additive removal, such as through pyrolyzing the additive. A heat treatment can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the bake of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiments for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, nonthermal treatments, including blanket UV exposure, or exposure to an oxidizing plasma such as O₂ may also be employed for similar purposes.

### EXAMPLES

### Example 1: Organotin Photoresist Films Comprising Vertical Composition Gradients

In this example, organotin coatings are deposition from organotin photoresist precursor solutions comprising an additive to form discrete layers and vertical composition gradients comprising organotin and additive.

A bulk photoresist precursor solution was prepared by combining isopropyl tin tris(sec-butoxide) with a solvent blend of 62% 1-pentanol by weight and 38% 1-propanol by weight such that the final solution had a Sn concentration of 0.2 M. Prior to formulation, the solvent blend was normalized to comprise water at a concentration of about 300 ppm by weight. The bulk precursor solution was divided into three aliquots, and a unique absorption profile modifier additive, shown in Table 1, was blended into each aliquot at a molar concentration of 0.04 M (0.2 ratio of additive relative to Sn).

TABLE 1

| Additive | Name | Structure |
|---|---|---|
| A | 1-Pyrene methanol | 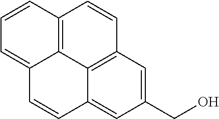 [SMILES: OCc1cc2ccc3cccc4ccc(c1)c2c34] |
| B | Pyrene methylamine HCl | 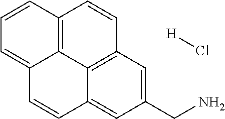 |
| C | 1-Pyrene butanol | 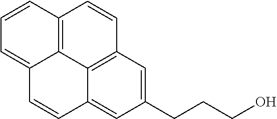 [SMILES: OCCCc1cc2ccc3cccc4ccc(c1)c2c34] |

Nine Si wafers were then coated with an organotin photoresist precursor solution comprising an absorption profile modifying additive via spin coating to form coatings having a thickness of about 70 to 110 nm. Applicant notes that the coatings deposited on WAF-01-WAF-09 are relatively thick in the context of EUV lithography. The coatings were intentionally deposited at relatively high thickness to improve the processing of ellipsometry data. The structural features observed herein are reasonably expected to manifest similarly in thinner coatings produced through adjustment of described process parameters for example, molar tin concentration of the precursor solution or spin coat speed. The wafers were then baked for 60 seconds at a temperature of 100° C., 150° C., or 200° C. The additive compositions and bake temperatures for each wafer is presented in Table 2.

TABLE 2

| | Additive Composition | |
|---|---|---|
| Wafer | (Concentration) | Bake Temperature |
| WAF-01 | A (0.2:Sn) | 100° C. |
| WAF-02 | A (0.2:Sn) | 150° C. |
| WAF-03 | A (0.2:Sn) | 200° C. |
| WAF-04 | B (0.2:Sn) | 100° C. |
| WAF-05 | B (0.2:Sn) | 150° C. |
| WAF-06 | B (0.2:Sn) | 200° C. |
| WAF-07 | C (0.2:Sn) | 100° C. |
| WAF-08 | C (0.2:Sn) | 150° C. |
| WAF-09 | C (0.2:Sn) | 200° C. |

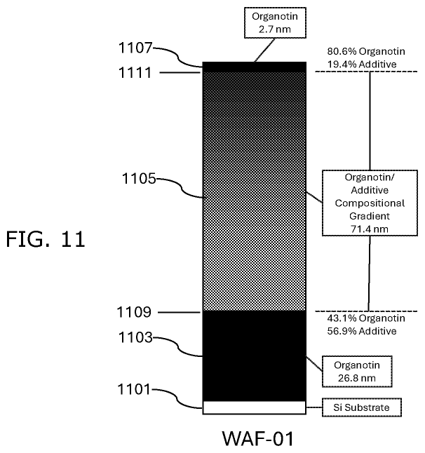

Each coated wafer was analyzed using ellipsometry modeling to determine the compositional makeup of the organotin coatings through the depth of the coatings. The modelling inputs the optical properties of the components to evaluate the output profile. Based on the optical response of the coatings, portions of the coating having optical properties (i.e. extinction coefficient and refractive index) consistent with the additives were attributed to additive containing material, regions having optical properties consistent with organotin were attributed to organotin containing material, and regions having both were attributed to blended material and weighted to determine approximate ratios of the components. The ellipsometry modeling indicated the existence of discrete layers comprising essentially organotin free of additive and discrete layers comprising a vertical concentration gradient of organotin and the additive. In most cases, the coatings were observed to comprise a discrete bottom layer comprising essentially organotin underlying an intermediate layer comprising a vertical composition gradient of organotin and the additive, and a discrete top layer comprising essentially organotin overlying the intermediate layer. Processing of some samples provided coatings lacking the discrete bottom layer. Table 3 presents the thickness of the top and bottom organotin layers, the thickness of the intermediate graduated layer, and the organotin concentration at the top and bottom of the graduated layer for each wafer, as determined through ellipsometry. A discrete bottom layer comprising organotin was not observed for WAF-04, WAF-07, and WAF-09, indicated in Table 3 as ‘**’ although these wafers did comprise a discrete top layer of organotin free of additive overlying a compositional gradient layer of organotin and additive. There was significant additive dependence on the specifics of the profile, but for this group of additives, the general nature of the profiles were similar. For reference, FIG. 11 shows a cross-sectional depiction of WAF-01, as determined through ellipsometry. WAF-01 comprises Si substrate 1101, bottom layer 1103 comprising essentially organotin overlying the substrate and underlying intermediate graduated layer 1105, and top layer 1107 consisting of essentially organotin overlying the graduated intermediate layer. The organotin concentration is determined at the bottom of the graduated layer 1109 and at the top of the graduated layer 1111. The cross sectional structures of the remaining wafers can be inferred from Table 3 similarly.

TABLE 3

| | Top Layer | | Bottom Layer | | Intermediate Layer | | Gradient Bottom | Gradient Top |
|---|---|---|---|---|---|---|---|---|
| Wafer | (Organotin) | | (Organotin) | | (Additive/Organotin) | | % Organotin | % Organotin |
| WAF-01 | 2.7 | nm | 26.8 | nm | 71.4 | nm | 43.1 | 80.6 |
| WAF-02 | 5.9 | nm | 15.6 | nm | 74.8 | nm | 50.0 | 79.8 |
| WAF-03 | 6.8 | nm | 0.3 | nm | 70.8 | nm | 83.3 | 87.7 |
| WAF-04 | 1.1 | nm | ** | | 103.0 | nm | 71.6 | 77.4 |
| WAF-05 | 3.5 | nm | 2.9 | nm | 69.7 | nm | 89.6 | 100.0 |
| WAF-06 | 3.2 | nm | 3.8 | nm | 65.3 | nm | 90.6 | 100.0 |
| WAF-07 | 1.3 | nm | ** | | 107.0 | nm | 76.8 | 78.5 |
| WAF-08 | 0.2 | nm | 2.2 | nm | 100.5 | nm | 71.7 | 82.1 |

| | | | | | | | |
|---|---|---|---|---|---|---|---|
| WAF-09 | 12.8 | nm | ** | 69.7 | nm | 78.5 | 95.3 |

Further analysis of the ellipsometry modeling revealed that the intermediate layers comprise a vertical composition gradient wherein the concentration of organotin increases from the bottom of the layer to the top of the layer. For WAF-01-06, which were deposited from solutions enhanced with 1-pyrene methanol or pyrene methylamine HCl, increased bake temperatures were consistent with less intense vertical composition gradients. For WAF-07-09 which were deposited from the solution comprising 1-pyrene butanol, increased bake temperatures were consistent with more intense vertical composition gradients. This suggests that the bake temperature can be a handle to fine-tune the vertical composition gradient's profile and obtain more control over the composition gradient's intensity. Improved control over the coating's composition gradient can be desirable to fine tune the lithographic performance of photoresist materials. While not wanting to be limited by theory, the lower concentration of organotin tending towards the bottom of the coating can decrease the effective dose received at the bottom of the coating. In combination with a lack of bottom layer for some embodiments, a lower concentration of organotin toward the bottom can reduce effects of radiation reflection and/or interactions between the organotin material and the substrate surface. The composition gradient can be such that the effective dose decreases through the depth of the coating which can offset mechanisms that produce overcut cross-sectional profiles in patterned features. The feature produced from coatings comprising a vertical compositional gradient can be less overcut, which can be quantified by the side wall angle.

### Example 2: Cross Sectional Uniformity Improvements with Absorption Profile Modifying Additives

In this example, an organotin precursor solution enhanced with an absorption profile modifying additive is prepared and photoresist patterns deposited therefrom are determined to exhibit a higher cross-sectional uniformity relative to an unenhanced precursor solution.

Two organotin photoresist precursor solutions PRX-1 and PRX-2 were prepared by combining a blend of 80 mol % tert-butyl tin tris(3-pentoxide) and 20 mol % methyl tin tris(tert-amyloxide) with a solvent blend comprising 62% 1-pentanol and 38% 1-propanol by weight such that the final solution had a molar Sn concentration of 0.061 M. An image profile modifying additive 1,4-Bis(trimethylsilyl)benzene, represented by the structure:

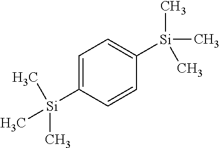

was added to the solution PRX-2 at a molar ratio of 0.1 relative to Sn, while no additive was added to solution PRX-1. Both solutions were deposited on to 300 mm Si wafers via spin coating to form organotin photoresist coatings having an approximate thickness of 26 nm, as determined by ellipsometry. The coatings were baked at a temperature of 100° C. for about 60 seconds prior to being patterned with 13.5 nm EUV radiation in an ASML NXE3400B scanner tool. The pattern consisted of 14 nm lines on a 28 nm pitch (14p28). The irradiated coatings were then baked at a temperature of 180° C. for about 60 seconds before being developed with a solution of 5 wt % acetic acid in propylene glycol methyl ether acetate (PGMEA). In a final hardbake step, the patterned coatings were bake at 250° C. for about 90 seconds. The cross-sectional profile of the resulting line-space patterns were then analyzed using transmission electron microscopy.

Photoresist structures may have a cross-sectional profile that is generally hourglass shaped due to t-topping at the upper region and footing at the lower region. The cross-sectional profile may therefore include three distinct, measurable points: i) a maximum width in an upper portion of the structure, ii) a second maximum width in a lower portion of the structure, and iii) a minimum width at an intermediate portion between the first and second maximum widths. Measurements of these three points may be used to characterize the cross-sectional uniformity of the structure through its height. A goal of lithography can be to reduce the difference between two or more of these widths to achieve a structure with improved cross-sectional uniformity through the height of the pattern. The upper maximum width, lower maximum width, and minimum width were measured using transmission electron microscopy for five photoresist pattern lines formed from PRX-1 and five photoresist pattern lines formed from PRX-2 and averaged to produce the values presented in Table 4.

TABLE 4

| | Upper | | Lower | |
|---|---|---|---|---|
| Photoresist | Maximum | Minimum | Maximum | Width |
| Solution | Width | Width | Width | Variation |
| PRX-1 | 12.4 nm | 11.6 nm | 14.3 nm | 2.7 nm |
| PRX-2 | 13.7 nm | 12.1 nm | 13.1 nm | 1.6 nm |

The photoresist pattern lines formed from photoresist solution PRX-2, which was enhanced with 1,4-Bis(trimethylsilyl)benzene, exhibited improved cross-sectional uniformity relative to those formed from photoresist solution PRX-1, which was not enhanced with an additive. The patterns formed from solution PRX-1 exhibited notable footing behavior, as the lower region had an averaged maximum width 2.7 nm larger than the averaged narrowest part of the feature. The averaged width variation, calculated as the difference between the averaged maximum and minimum width of the pattern was relatively high for the pattern formed from PRX-1 at 2.7 nm, which is generally undesirable for pattern transfer quality and consistency. The photoresist solution PRX-2, which was enhanced with an absorption profile modifying additive, exhibited a reduced magnitude of footing relative to PRX-1, with a width difference of 1.0 nm from the minimum width to the lower maximum width. The cross-sectional uniformity was also improved for the patterns formed from PRX-2 relative to PRX-1, with an averaged width variation of just 1.6 nm, indicating a more uniform profile cross section. These results indicate that the addition of 1,4-Bis(trimethylsilyl)benzene to an organotin photoresist precursor solution can improve the cross-sectional uniformity of patterned features formed therefrom. It more generally suggests that the addition of absorption profile modifying additives can be an effective means to reduce cross-sectional pattern deformities such as t-topping or footing.

Furthermore, patterns formed from solution PRX-2 exhibited lower feature to feature width variation at the bottom of the features than patterns formed from solution PRX-1. Feature to feature variation of the lower maximum width was quantified by the interquartile range (IQR), which was about 1.3 nm for PRX-1 and about 0.8 nm for PRX-2. These results indicate that inclusion of 1,4-bis(trimethylsilyl)benzene in organotin photoresist precursor solution can improve feature to feature critical dimension uniformity of patterns formed therefrom. Improved feature to feature uniformity can be desirable for improving process consistency, especially during the pattern transfer etch step.

### FURTHER INVENTIVE CONCEPTS

A1. A method for forming a photo-patternable material comprising a water activity modulating additive, absorption modulating additive and/or radical scavenger additive on a substrate, the method comprising:
   depositing the enhanced water activity modulating additive, absorption modulating additive, and/or a radical scavenger additive to achieve an enhanced average concentration of additive within the top 50% of the thickness of the photo-patternable material relative to the average additive concentration through the thickness, wherein the average additive concentration is from about 0.5 wt % to about 35 wt % and the enhanced average concentration is at least about 25% greater than the average concentration, the photo-patternable material comprising organotin moieties represented by RSn, where R forms a carbon tin bond and has from 1 to 31 carbon atoms.
A2. The method of inventive concept A1 wherein the depositing comprises applying an additive solution comprising solvent and additive over a previously formed coating comprising organotin and an amorphous oxo-hydroxo network.
A3. The method of inventive concept A2 wherein the additive solution further comprises an organotin compound represented by the formula RSnL₃, where R is an organyl group with from 1 to 31 carbon atoms and L is a hydrolysable ligand.
A4. The method of inventive concept A3 wherein the additive composition is present at a molar ratio relative to Sn from 0.05 to 5.
A5. The method of inventive concept A3 or inventive concept A4 wherein R is specified by any one of claims 11-13.
A6. The method of any one of inventive concepts A3-A5 wherein L is selected from the group consisting of alkylamido, dialkylamido, siloxo, silylamido, disilylamido, aryloxo, alkynido, amidato, azido, amidinato, and imido, and fluorinated analogues thereof, or wherein L is —OR^{L}, where R^{L} is an alkyl group having 1 to 11 carbon atoms.
A7. The method of any one of inventive concepts A3-A6 wherein the concentration of tin cation is from 0.0025 M to 1.0 M.
A8. The method of any one of inventive concepts A3-A7 wherein the solution has a molar ratio of additive composition relative to Sn from 0.1 to 2.5.
A9. The method of any one of inventive concepts A2-A8 wherein the previously formed coating is in a gel state at the time of depositing the additive.
A10. The method of any one of inventive concepts A2-A9 wherein the previously formed coating comprises an initial water activity modulating additive.
A11. The method of inventive concept A10 wherein the initial water activity modulating additive is the same composition as the water activity modulating additive and wherein the enhanced concentration of water activity modulating additive is at least about 25% relative to the average concentration of water activity modulating additive and enhanced water activity modulating additive.
A12. The method of inventive concept A10 wherein the initial water activity modulating additive is a different composition from the water activity modulating additive.
A13. The method of any one of inventive concepts A2-A12 wherein the previously formed coating is free of additives.
A14. The method of any one of inventive concepts A1-A13 further comprising depositing an underlayer comprising an absorption modulating additive prior to formation of the photo-patternable material over the underlayer.
A15. The method of inventive concept A14 wherein the underlayer comprises organotin moieties.
A16. The method of any one of inventive concepts A1-A15 wherein the water activity modulating additive is represented by the chemical formula: X—R^{Q}-Q, wherein:
   1) Q is a low-polarity hydrocarbyl moiety with optional silicon atom substitution and with optional sulfur atom substitution having from 9 to 31 total carbon, silicon and sulfur atoms, R^{Q} is an alkyl group with 1 to 8 carbon atoms or a silyl group, and X is H or a polar functional group comprising a heteroatom, or
   2) Q is represented by the chemical formula —NR²R³, R² and R³ are independently hydrogen or an alkyl group, X is H and R^{Q}, R², and R³ independently are H or an alkyl group and collectively have from 6 to 30 carbon atoms while forming an unhindered amine or
   3) Q is represented by the chemical formula R^{a}—C≡C—, where R^{a} is a hydrogen or an alkyl group with 1 to 8 carbon atoms R^{Q} is an alkyl group with 1 to 8 carbon atoms and X is an OH, or
   4) Q is a hydrocarbyl group with one or more alkene groups, 2 to 31 carbon atoms and no heteroatoms, X is OH and R^{Q} is an alkyl group having 1 to 8 carbon atoms, or
   5) Q is represented by —R⁴NR⁵R⁶, R^{Q} is an alkyl group with 1 to 8 carbon atoms or an aromatic group with 6 to 16 carbon atoms, and X is R³R²NR¹—, where R¹ is a bond or an alkyl group with 1 to 8 carbon atoms, R³ and R⁴ are independently a bond or an alkyl group with 1 to 8 carbon atoms, and R², R⁵, R⁶ are independently H or an alkyl group with 1 to 8 carbon atoms, and
      wherein the additive composition is present overall at a molar ratio relative to Sn from 0.01 to 10.
A17. The method of inventive concept A16 wherein the water modulating additive composition is specified by the additive of any one of claims 2-9 that is blended into the solution.
A18. The method of any one of inventive concepts A1-A17 wherein the organic solvent is an alcohol, an ether, an ester, a ketone, an alkane, an aromatic hydrocarbon, or a combination thereof.
A19. The method of any one of inventive concepts A1-A17 wherein the organic solvent comprises a blend of two or more alcohols selected from the group consisting of methanol, ethanol, propanol, butanol, pentanol, hexanol, heptanol, octanol, and isomers thereof.
A20. The method of any one of inventive concepts A3-A19 wherein the solution further comprises water at a selected concentration from 200 ppm to 10,000 ppm by weight.
A21. The method of any one of inventive concepts A1-A20 wherein the solution comprises a radical scavenger additive at a concentration from 0.000025 M to 0.4 M.
B1. A coated substrate comprising:
   a substrate and
   a coating material comprising organotin moieties within a matrix comprising hydroxide ligands and oxo-ligands in an amorphous network and an additive composition, which as added to a precursor composition, is represented by the chemical formula: X—R^{Q}-Q, wherein:
   1) Q is a low-polarity hydrocarbyl moiety with optional silicon atom substitution and with optional sulfur atom substitution having from 9 to 31 total carbon, silicon and sulfur atoms and optionally with an aromatic sulfur atom substitution, R^{Q} is an alkyl group with 1 to 8 carbon atoms or a silyl group, and X is H or a polar functional group comprising a heteroatom, or
   2) Q is represented by the chemical formula —NR²R³, R² and R³ are independently hydrogen or an alkyl group, X is H and R^{Q}, R², and R³ collectively have from 6 to 30 carbon atoms while forming an unhindered amine or
   3) Q is represented by the chemical formula R^{a}—C≡C—, where R^{a} is a hydrogen or an alkyl group with 1 to 8 carbon atoms, R^{Q} is an alkyl group with 1 to 8 carbon atoms and X is an OH, or
   4) Q is a hydrocarbyl group with one or more alkene groups, 2 to 31 carbon atoms and no heteroatoms, X is OH and R^{Q} is an alkyl group having 2 to 8 carbon atoms, or
   5) Q is represented by R⁵R⁶NR⁴—, R^{Q} is an alkyl group with 1 to 8 carbon atoms or an aromatic group with 6 to 16 carbon atoms, and X is —R¹NR²R³, where R¹ is a bond or an alkyl group with 1 to 8 carbon atoms, R⁴ is an alkyl group with 1 to 8 carbon atoms, and R², R³, R⁵, R^{Q} are independently H or an alkyl group with 1 to 8 carbon atoms, and
      wherein the additive composition is present at a molar ratio relative to Sn from 0.05 to 10 and wherein molecules of the additive compositions may or may not be ligated to tin.
B2. The coated substrate of inventive concept B1 wherein the organotin moieties are represented by RSn, where R is an organyl group with from 1 to 31 and forms a carbon-tin bond.
B3. The coated substrate of inventive concept B2 wherein the R group is specified by any one of claim 11-13, 19 or 20.
B4. The coated substrate of any one of inventive concepts B1-B3 wherein the water activity modulating additive can be substantially removed in a bake step, which is at a selected temperature from about 100° C. to about 450° C.
B5. The coated substrate of any one of inventive concepts B1-B4 wherein the water activity modulating additive influences radiation absorption and condensation.
B6. The coated substrate of any one of inventive concept B1-B5 wherein the water activity modulating additive has a nonuniform concentration through the thickness of the coating.
B7. The coated substrate of inventive concept B6 wherein an enhanced average concentration of water activity modulating additive is located in a top 50% layer of the coating thickness relative to the average concentration through the full coating thickness.
B8. The coated substrate of inventive concept B6 wherein a top 35% layer of the coating has an enhanced average concentration of additive that is at least about 25% greater than the average concentration through the full thickness.
B9. The coated substrate of inventive concept B6 wherein an enhanced average concentration of water activity modulating additive is located in a bottom 20% layer of the coating thickness relative to the average concentration through the full thickness, wherein the enhanced average concentration is at least about 10% greater than the average concentration through the full thickness.
B10. The coated substrate of inventive concept B6 wherein a concentration gradient of water activity modulating additive is located within an internal 50% thickness portion of the coating.
B11. The coated substrate of inventive concept B10 wherein concentration of water activity modulating additive at the top of the gradient is at least 10% greater than the concentration at the bottom of the gradient.
B12. The coated substrate of inventive concept B10 wherein concentration of water activity modulating additive at the top of the gradient is at least 10% less than the concentration at the bottom of the gradient.
B13. The coated substrate of any one of inventive concepts B1-B12 wherein the additive is specified by the additive of any one of claims 2-9 that is blended into the solution.
B14. The coated substrate of any one of inventive concepts B1-B13 wherein the substrate comprises silicon.
B15. The coated substrate of any one of inventive concepts B1-B14 wherein the coating material further comprises a radical scavenger additive.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art. A person of ordinary skill in the art is notified that the assertions above regarding the contemplation of subranges within explicit ranges are sincerely intended to provide explicit written description for the subranges, as clearly suggested, even though not explicitly written and that the subranges are not believed to change the character of the associated invention, although of course the specific values of parameters will certainly quantitively change corresponding results obtained, which could influence patentability even though the basic character of the invention may not be changing, in view of the potential nature of the state of the art known or unknown at filing given that inventiveness may follow from the factual details. A person of ordinary skill in the art is further notified that upper and lower values of explicit ranges and values within explicit ranges are intended to provide explicit written description for endpoints of subranges, furthermore explicit disclosure of upper and/or lower values of explicitly ranges of a certain feature are intended to be disclosed as upper and/or lower values for additional ranges, including subranges.

What is claimed is:

1. A solution comprising a blend of:
an organic solvent,
an organotin composition represented by the formula RSnL₃, where R is an organyl group with from 1 to 31 carbon atoms and L is a hydrolysable ligand and
one or more additive compositions represented by the chemical formula: X—R^{Q}-Q, wherein:
1) Q is a low-polarity hydrocarbyl moiety with optional silicon atom substitution and with optional sulfur atom substitution having from 9 to 31 total carbon, silicon and sulfur atoms, R^{Q} is an alkyl group with 1 to 8 carbon atoms or a silyl group, and X is H or a polar functional group comprising a heteroatom, or
2) Q is represented by the chemical formula —NR²R³, R² and R³ are independently hydrogen or an alkyl group, X is H and R^{Q}, R², and R³ independently are H or an alkyl group and collectively have from 6 to 30 carbon atoms while forming an unhindered amine or
3) Q is represented by the chemical formula R^{a}—C≡C—, where R^{a} is a hydrogen or an alkyl group with 1 to 8 carbon atoms R^{Q} is an alkyl group with 1 to 8 carbon atoms and X is an OH, or
4) Q is a hydrocarbyl group with one or more alkene groups, 2 to 31 carbon atoms and no heteroatoms, X is OH and R^{Q} is an alkyl group having 1 to 8 carbon atoms, or
5) Q is represented by —R⁴NR⁵R⁶, R^{Q} is an alkyl group with 1 to 8 carbon atoms or an aromatic group with 6 to 16 carbon atoms, and X is R³R²NR¹—, where R¹ is a bond or an alkyl group with 1 to 8 carbon atoms, R⁴ is a bond or an alkyl group with 1 to 8 carbon atoms, and R², R³, R⁵, R⁶ are independently H or an alkyl group with 1 to 8 carbon atoms, and
wherein the additive composition is present at a molar ratio relative to Sn from 0.01 to 10.

2. The solution of claim 1 wherein the additive composition is represented by the formula CₙH₂ₙ₋₁CH₂OH and 2≤n≤11.

3. The solution of claim 1 wherein the additive composition is represented by the formula CₘH₂ₘ₋₃CH₂OH and 2≤m≤11.

4. The solution of claim 1 wherein the additive composition is 1,4-bis(trimethylsilyl)benzene.

5. The solution of claim 1 wherein the additive composition is represented by the formula NR¹R²R³, where R¹ is a linear alkyl group having 1 to 6 carbon atoms and R² and R³ are H.

6. The solution of claim 1 wherein the additive composition is represented by the formula of option 5) and R^{Q} comprises an aromatic group.

7. The solution of claim 1 wherein the additive composition is represented by option 1) and wherein Q comprises a polycyclic aromatic group.

8. The solution of claim 1 wherein the additive composition is represented by option 1) and Q comprises one or more Si atoms.

9. The solution of claim 1 wherein the additive composition is represented by option 1) and X is a hydroxyl group, a thiol group, an amine or a halogen.

10. The solution of claim 1 wherein the additive composition is present at a molar ratio relative to Sn from 0.05 to 5.

11. The solution of claim 1 wherein R is a branched alkyl ligand.

12. The solution of claim 1 wherein R is methyl, ethyl, n-propyl, n-butyl, t-butyl, isopropyl, sec-butyl, isobutyl, n-pentyl, isopentyl, neopentyl, or sec-pentyl or a combination thereof.

13. The solution of claim 1 where R is cyclohexyl, cyclopentyl, cyclobutyl, cyclopropyl, 1-adamntyl, or 2-adamantyl or a combination thereof.

14. The solution of claim 1 wherein L is selected from the group consisting of alkylamido, dialkylamido, siloxo, silylamido, disilylamido, aryloxo, alkynido, amidato, azido, amidinato, and imido, and fluorinated analogues thereof.

15. The solution of claim 1 wherein L is —OR^{L}, where R^{L} is an alkyl group having 1 to 11 carbon atoms.

16. The solution of claim 1 wherein the concentration of tin cation is from 0.0025 M to 1.0 M.

17. The solution of claim 1 further comprising hydrolysis products of RSnL₃.

18. The solution of claim 1 further comprising a second organotin composition represented by the formula R′SnL′₃ wherein R′ is an organyl ligand having from 1 to 31 carbon atoms and different from R and L′ is a hydrolysable ligand that is the same or different than L.

19. The solution of claim 1 wherein R is substituted with one or more heteroatoms selected from the group consisting of O, S, Se, Te, N, Si, Ge, Sn, F, and I.

20. The solution of claim 1 wherein R is substituted with one or more heteroatoms functional groups selected from the group consisting of cyano, thio, silyl, ether, keto, ester, acetal, ketal and halogenated groups.

21. The solution of claim 1 wherein the organic solvent is an alcohol, an ether, an ester, a ketone, an alkane, an aromatic hydrocarbon, or a combination thereof.

22. The solution of claim 1 wherein the organic solvent comprises a blend of two or more alcohols selected from the group consisting of methanol, ethanol, propanol, butanol, pentanol, hexanol, heptanol, octanol, and isomers thereof.

23. The solution of claim 1 having a molar ratio of additive composition relative to Sn from 0.1 to 2.5.

24. The solution of claim 1 further comprising water at a selected concentration from 200 ppm to 10,000 ppm by weight.

25. The solution of claim 1 further comprising a radical scavenger additive at a concentration from 0.000025 M to 0.4 M.
